(19) United States
(12) Patent Application Publication
(10) Pub. No.: US 2026/0354263 A1
(43) Pub. Date: Nov. 5, 2026

(54) BONDED ASSEMBLIES INCLUDING THROUGH-SUBSTRATE VIA STRUCTURES AND THROUGH-DIELECTRIC VIA STRUCTURES AND METHODS FOR FORMING THE SAME

(71) Applicant: Sandisk Technologies, Inc., Milpitas, CA (US)

(72) Inventors: Guangyuan LI, Santa Clara, CA (US); Yuji TOTOKI, Milpitas, CA (US); Mitsuteru MUSHIGA, Yokkaichi (JP); Fumiaki TOYAMA, Cupertino, CA (US)

(21) Appl. No.: 19/198,514

(22) Filed: May 5, 2025

(51) Int. Cl. H10W 90/00; H10B 80/00; H10W 20/20; H10W 80/00

(52) U.S. Cl. CPC H10W 90/00; H10W 20/20; H10B 80/00; H10W 80/312; H10W 80/327; H10W 90/792

(57) ABSTRACT

A semiconductor structure includes a bonded assembly of a memory die and a memory controller die. The memory die contains an alternating stack of insulating layers and electrically conductive layers and memory opening fill structures including vertical stacks of memory elements. A memory-die dielectric material portion is laterally offset from the alternating stack within the memory die. The controller die includes a memory controller circuit for controlling operation of the memory die and further includes controller-die front dielectric material layers embedding controller-die front metal interconnect structures. An inter-die connection via structure vertically extends through the memory-die dielectric material portion and a first subset of the controller-die front dielectric material layers and contacts one of the controller-die front metal interconnect structures.

### FIELD

The present disclosure relates generally to the field of semiconductor devices, and particularly to semiconductor structures including composite dies containing through-substrate via structures and inter-die connection via structures and methods for forming the same.

### BACKGROUND

Flash memory devices include NAND and NOR memory devices. Such memory devices may be formed by sequentially depositing memory device layers over a driver circuit located on a silicon wafer.

### SUMMARY

According to an aspect of the present disclosure, a semiconductor structure comprises: a first memory die comprising a first alternating stack of first insulating layers and first electrically conductive layers, first memory opening fill structures vertically extending through the first alternating stack and comprising a respective vertical stack of first memory elements, a first memory-die dielectric material portion laterally offset from the first alternating stack, and first memory-die front dielectric material layers embedding first memory-die front metal interconnect structures and first memory-die front bonding structures; a first memory controller die comprising a first controller-die substrate, a first memory controller circuit configured to control operation of the first memory die and located on the first controller-die substrate, and first controller-die front dielectric material layers embedding first controller-die front metal interconnect structures and first controller-die front bonding structures that are bonded to the first memory-die front bonding structures; and a first inter-die connection via structure vertically extending through the first memory-die dielectric material portion and a first subset of the first controller-die front dielectric material layers and having a first end surface contacting one of the first controller-die front metal interconnect structures.

According to another aspect of the present disclosure, a method of forming a semiconductor structure is provided, which comprises: providing a first memory die comprising a first carrier substrate, a first alternating stack of first insulating layers and first electrically conductive layers, first memory opening fill structures vertically extending through the first alternating stack and comprising a respective vertical stack of first memory elements, a first memory-die dielectric material portion laterally offset from the first alternating stack, and first memory-die front dielectric material layers embedding first memory-die front metal interconnect structures and first memory-die front bonding structures; providing a first memory controller die comprising a first controller-die substrate, a first memory controller circuit configured to control operation of the first memory die and located on the first controller-die substrate, and first controller-die front dielectric material layers embedding first controller-die front metal interconnect structures and first controller-die front bonding structures; bonding the first controller-die front bonding structures to the first memory-die front bonding structures; removing the first carrier substrate; and forming a first inter-die connection via structure through the first memory-die dielectric material portion and a first subset of the first controller-die front dielectric material layers and directly on one of the first controller-die front metal interconnect structures.

### BRIEF DESCRIPTION OF THE DRAWINGS

FIG. 1 is a schematic vertical cross-sectional view of an exemplary in-process memory die after formation of a backside dielectric layer, in-process source-level material layers, an alternating stack of insulating layers and sacrificial material layers having stepped surfaces, and a retro-stepped dielectric material portion over a carrier substrate according to an embodiment of the present disclosure.

FIG. 2A is a schematic vertical cross-sectional view of the exemplary in-process memory die after forming memory openings according to an embodiment of the present disclosure. FIG. 2B is a top-down view of the exemplary in-process memory die of FIG. 2A. The vertical plane A-A′ is the cut plane of the vertical cross-sectional view of FIG. 2A. FIG. 2C is a top-down view of the exemplary in-process memory die at the processing steps of FIGS. 2A and 2B.

FIGS. 3A-3D are sequential vertical cross-sectional views of a memory opening during formation of a memory opening fill structure according to an embodiment of the present disclosure.

FIG. 4 is a vertical cross-sectional view of the exemplary in-process memory die after formation of memory opening fill structures according to an embodiment of the present disclosure.

FIG. 5A is a vertical cross-sectional view of the exemplary in-process memory die after formation of a contact-level dielectric layer, a patterned hard mask layer, lateral isolation trenches, and discrete through-stack openings according to an embodiment of the present disclosure. FIG. 5B is a top-down view of the exemplary in-process memory die of FIG. 5A. The vertical plane A-A′ is the cut plane of the vertical cross-sectional view of FIG. 5A. FIG. 5C is a top-down view of the exemplary in-process memory die including the exemplary in-process memory die at the processing steps of FIGS. 5A and 5B.

FIG. 6 is a vertical cross-sectional view of the exemplary in-process memory die after vertical extension of the discrete through-stack openings according to an embodiment of the present disclosure.

FIG. 7 is a vertical cross-sectional view of the exemplary in-process memory die after formation of sacrificial lateral isolation trench fill structures and sacrificial through-stack opening fill structures according to an embodiment of the present disclosure.

FIG. 8 is a vertical cross-sectional view of the exemplary in-process memory die after removal of the sacrificial lateral isolation trench fill structures according to an embodiment of the present disclosure.

FIG. 9 is a vertical cross-sectional view of the exemplary in-process memory die after formation of a source cavity according to an embodiment of the present disclosure.

FIG. 10 is a vertical cross-sectional view of the exemplary in-process memory die after formation of a source contact layer and dielectric capping liners according to an embodiment of the present disclosure.

FIG. 11 is a vertical cross-sectional view of the exemplary in-process memory die after formation of laterally-extending cavities according to an embodiment of the present disclosure.

FIG. 12 is a vertical cross-sectional view of the exemplary in-process memory die after formation of electrically conductive layers according to an embodiment of the present disclosure.

FIG. 13 is a vertical cross-sectional view of the exemplary in-process memory die

after formation of lateral isolation trench fill structures and contact via structures according to an embodiment of the present disclosure.

FIG. 14 is a vertical cross-sectional view of the exemplary in-process memory die after removal of the sacrificial through-stack opening fill structures according to an embodiment of the present disclosure.

FIG. 15 is a vertical cross-sectional view of the exemplary in-process memory die after formation of tubular dielectric spacers and through-stack via structures according to an embodiment of the present disclosure.

FIG. 16 is a vertical cross-sectional view of the exemplary in-process memory die after formation of layer contact via structures, drain contact via structures, and peripheral connection via structures according to an embodiment of the present disclosure.

FIG. 17 is a vertical cross-sectional view of the exemplary in-process memory die after formation of a memory die according to an embodiment of the present disclosure.

FIG. 18 is a vertical cross-sectional view of an exemplary in-process memory-controller die after formation of controller semiconductor devices and controller-die front dielectric material layers and controller-die front metal interconnect structures according to an embodiment of the present disclosure.

FIG. 19 is a vertical cross-sectional view of the exemplary in-process memory-controller die after formation of through-substrate via cavities according to an embodiment of the present disclosure.

FIG. 20 is a vertical cross-sectional view of the exemplary in-process memory controller die after formation of dielectric isolation liners and through-substrate via structures according to an embodiment of the present disclosure.

FIG. 21 is a vertical cross-sectional view of an exemplary memory controller die after formation of additional controller-die front dielectric material layers, additional controller-die front metal interconnect structures, and controller-die front bonding structures according to an embodiment of the present disclosure.

FIG. 22 is a vertical cross-sectional view of a first exemplary bonded assembly of a memory die and a memory-controller die according to an embodiment of the present disclosure.

FIG. 23 is a vertical cross-sectional view of the first exemplary bonded assembly after removal of a carrier substrate from the memory die according to an embodiment of the present disclosure.

FIG. 24 is a vertical cross-sectional view of the first exemplary bonded assembly after formation of memory-die backside contact via structures according to an embodiment of the present disclosure.

FIG. 25 is a vertical cross-sectional view of the first exemplary bonded assembly after formation of inter-die connection via cavities according to an embodiment of the present disclosure.

FIG. 26 is a vertical cross-sectional view of the first exemplary bonded assembly after formation of inter-die connection via structures according to an embodiment of the present disclosure.

FIG. 27 is a vertical cross-sectional view of the first exemplary bonded assembly after formation of a memory-die backside dielectric material layer and memory-die backside metal interconnect structures according to an embodiment of the present disclosure.

FIG. 28 is a vertical cross-sectional view of the first exemplary bonded assembly after formation of additional memory-die backside dielectric material layers, additional memory-die backside metal interconnect structures, and memory-die backside bonding structures according to an embodiment of the present disclosure.

FIG. 29 is a magnified view of an alternative configuration of the first exemplary bonded assembly according to an embodiment of the present disclosure.

FIG. 30 is a vertical cross-sectional view of the first exemplary bonded assembly after formation of controller-die backside dielectric material layers, controller-die backside metal interconnect structures, and controller-die backside bonding structures according to an embodiment of the present disclosure.

FIG. 31 is a vertical cross-sectional view of a second exemplary bonded assembly after bonding two bonded assemblies of a respective memory die and a respective memory controller die according to an embodiment of the present disclosure.

FIG. 32 is a vertical cross-sectional view of the second exemplary bonded assembly after thinning controller-die substrates according to an embodiment of the present disclosure.

FIG. 33 is a vertical cross-sectional view of the second exemplary bonded assembly after formation of controller-die backside dielectric material layers, controller-side backside metal interconnect structures, and controller-die backside bonding structures according to an embodiment of the present disclosure.

FIG. 34A is a vertical cross-sectional view of an exemplary structure including multiple instances of composite dies according to an embodiment of the present disclosure. FIG. 34B is a vertical cross-sectional view of another exemplary structure including multiple instances of composite dies according to an embodiment of the present disclosure.

### DETAILED DESCRIPTION

As discussed above, the embodiments of the present disclosure are directed to semiconductor structures including composite dies containing through-substrate via structures and inter-die connection via structures and methods for forming the same, the various aspects of which are described below.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which may be the smallest unit that can be erased in a single erase operation. Alternatively, subblocks may be the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

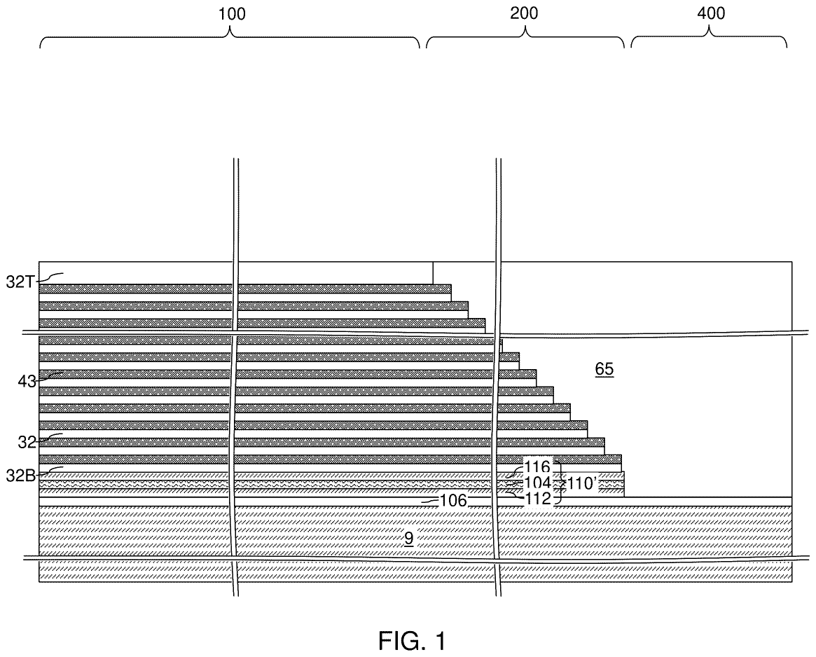

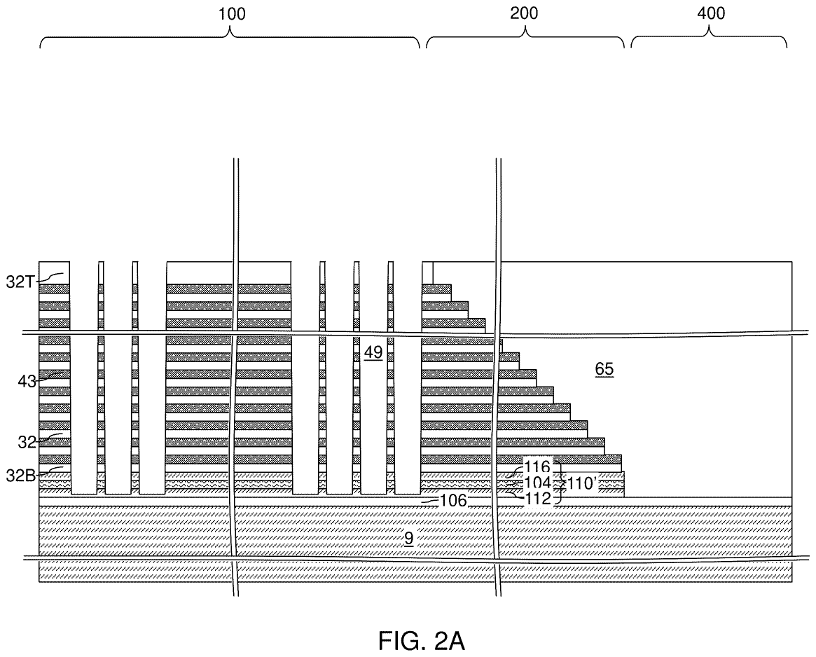

Referring to FIG. 1, an exemplary in-process memory die according to an embodiment of the present disclosure is illustrated. The exemplary in-process memory die comprises a carrier substrate 9, which may be a semiconductor substrate, a dielectric substrate, or a conductive substrate. For example, the carrier substrate 9 may comprise a commercially available silicon wafer. Alternatively, the carrier substrate 9 may comprise any material that may be removed selectively to the materials of a first memory-die proximal dielectric material layer 106 and a retro-stepped dielectric material portion 65 to be subsequently formed.

A dielectric material layer can be formed on a top surface of the carrier substrate 9. The dielectric material layer can be subsequently employed as a stopping material layer for a process that removes the carrier substrate 9, and is herein referred to as a first memory-die proximal dielectric material layer 106, or as a stopper dielectric layer. The first memory-die proximal dielectric material layer 106 comprises and/or consists essentially of a dielectric material, such as undoped silicate glass (i.e., silicon oxide), a doped silicate glass, or silicon nitride. If a polishing process such as a chemical mechanical polishing process is employed to subsequently remove the carrier substrate 9, the first memory-die proximal dielectric material layer 106 may be subsequently employed as a polishing stopper material layer. If an etch process such as a wet etch process is employed to subsequently remove the carrier substrate 9, the first memory-die proximal dielectric material layer 106 may be subsequently employed as an etch stop material layer. In one embodiment, the first memory-die proximal dielectric material layer 106 comprises a dielectric material such as undoped silicate glass, a doped silicate glass, or silicon nitride. The thickness of the first memory-die proximal dielectric material layer 106 may be in a range from 50 nm to 600 nm, such as from 100 nm to 300 nm, although lesser and greater thicknesses may also be employed.

In-process source-level material layers 110′ can be formed over the first memory-die proximal dielectric material layer 106. The in-process source-level material layers 110′ may include various layers that are subsequently modified to form source-level material layers. The source-level material layers, upon formation, include a source contact layer that functions as a common source region for vertical field effect transistors of a three-dimensional memory device. In one embodiment, the in-process source-level material layers 110′ may include, from bottom to top, a lower source-level semiconductor layer 112, an optional lower sacrificial liner (not shown), a source-level sacrificial layer 104, an optional upper sacrificial liner (not shown), and an upper source-level semiconductor layer 116.

The lower source-level semiconductor layer 112 and the upper source-level semiconductor layer 116 may include a doped semiconductor material such as doped polysilicon or doped amorphous silicon. The conductivity type of the lower source-level semiconductor layer 112 and the upper source-level semiconductor layer 116 may be the opposite of the conductivity of vertical semiconductor channels to be subsequently formed. For example, if the vertical semiconductor channels to be subsequently formed have a doping of a first conductivity type, the lower source-level semiconductor layer 112 and the upper source-level semiconductor layer 116 have a doping of a second conductivity type that is the opposite of the first conductivity type. The thickness of each of the lower source-level semiconductor layer 112 and the upper source-level semiconductor layer 116 may be in a range from 10 nm to 300 nm, such as from 20 nm to 150 nm, although lesser and greater thicknesses may also be used.

The source-level sacrificial layer 104 includes a sacrificial material that may be removed selectively to the lower sacrificial liner (or selectively to the lower source-level semiconductor layer 112) and the upper sacrificial liner (or selectively to the upper source-level semiconductor layer 116). In one embodiment, the source-level sacrificial layer 104 may include a semiconductor material such as undoped amorphous silicon or a silicon-germanium alloy with an atomic concentration of germanium greater than 20%. The thickness of the source-level sacrificial layer 104 may be in a range from 30 nm to 400 nm, such as from 60 nm to 200 nm, although lesser and greater thicknesses may also be used. The lower sacrificial liner (if present) and the upper sacrificial liner (if present) include materials that may function as an etch stop material during removal of the source-level sacrificial layer 104. For example, the lower sacrificial liner and the upper sacrificial liner may include silicon oxide, silicon nitride, and/or a dielectric metal oxide. In one embodiment, each of the lower sacrificial liner and the upper sacrificial liner may include a silicon oxide layer having a thickness in a range from 2 nm to 30 nm, although lesser and greater thicknesses may also be used.

An alternating stack of first material layers and second material layers can be formed over the in-process source-level material layers 110′. In an alternative embodiment, the in-process source-level material layers 110′ and the first memory-die proximal dielectric material layer 106 may be omitted, and the alternating stack is formed directly on a surface of the carrier substrate 9. In the alternating stack, the first material layers may be insulating layers, and the second material layers may be spacer material layers. In one embodiment, the spacer material layers may comprise sacrificial material layers 42. In this case, an alternating stack (32, 42) of insulating layers 32 and sacrificial material layers 42 can be formed over the in-process source-level material layers 110′. The insulating layers 32 comprise an insulating material such as undoped silicate glass or a doped silicate glass, and the sacrificial material layers 42 comprise a sacrificial material, such as silicon nitride or a silicon-germanium alloy. In one embodiment, the insulating layers 32 (i.e., the first material layers) may comprise silicon oxide layers, and the sacrificial material layers 42 (i.e., the second material layers) may comprise silicon nitride layers.

The alternating stack (32, 42) may comprise multiple repetitions of a unit layer stack including an insulating layer 32 and a sacrificial material layer 42. The total number of repetitions of the unit layer stack within the alternating stack (32, 42) may be, for example, in a range from 8 to 1,024, such as from 32 to 256, although lesser and greater number of repetitions may also be employed. The topmost one of the insulating layers 32 is hereafter referred to as a topmost insulating layer 32T. The bottommost one of the insulating layers 32 is an insulating layer 32 that is most proximal to the carrier substrate 9, and is herein referred to as a bottommost insulating layer 32B.

Each of the insulating layers 32 other than the topmost insulating layer 32T may have a thickness in a range from 20 nm to 100 nm, such as from 30 nm to 60 nm, although lesser and greater thicknesses may also be employed. Each of the sacrificial material layers 42 may have a thickness in a range from 20 nm to 100 nm, such as from 30 nm to 60 nm, although lesser and greater thicknesses may also be employed. In one embodiment, the topmost insulating layer 32T may have a thickness of about twice the thickness of other insulating layers 32.

Stepped surfaces are formed in a contact region 200. As used herein, “stepped surfaces” refer to a set of surfaces that include at least two horizontal surfaces and at least two vertical surfaces such that each horizontal surface is adjoined to a first vertical surface that extends upward from a first edge of the horizontal surface, and is adjoined to a second vertical surface that extends downward from a second edge of the horizontal surface. A stepped cavity is formed within the volume from which portions of the alternating stack (32, 42) are removed through formation of the stepped surfaces. A “stepped cavity” refers to a cavity having stepped surfaces.

The stepped cavity can have various stepped surfaces such that the horizontal cross-sectional shape of the stepped cavity changes in steps as a function of the vertical distance from the top surface of the in-process source-level material layers 110′. In one embodiment, the stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each sacrificial material layer 42 other than a topmost sacrificial material layer 42 within the alternating stack (32, 42) laterally extends farther than any overlying sacrificial material layer 42 within the alternating stack (32, 42) in the terrace region. The stepped surfaces of the alternating stack (32, 42) continuously extend from a bottommost layer within the alternating stack (32, 42) (such as the bottommost insulating layer 32B) to a topmost layer within the alternating stack (32, 42) (such as the topmost insulating layer 32T).

A retro-stepped dielectric material portion 65 (i.e., an insulating fill material portion) can be formed in the stepped cavity by deposition of a dielectric material therein. For example, a dielectric material such as silicon oxide can be deposited in the stepped cavity. Excess portions of the deposited dielectric material can be removed from above the top surface of the topmost insulating layer 32T, for example, by chemical mechanical planarization (CMP). The remaining portion of the deposited dielectric material filling the stepped cavity constitutes the retro-stepped dielectric material portion 65. As used herein, a “retro-stepped” element refers to an element that has stepped surfaces and a horizontal cross-sectional area that increases monotonically as a function of a vertical distance from a top surface of a substrate on which the element is present. If silicon oxide is employed for the retro-stepped dielectric material portion 65, the silicon oxide of the retro-stepped dielectric material portion 65 may, or may not, be doped with dopants such as B, P, and/or F.

Optionally, drain-select-level isolation structures (not shown) can be formed through the topmost insulating layer 32T and a subset of the sacrificial material layers 42 located at drain-select-levels. The drain-select-level isolation structures can be formed, for example, by forming drain-select-level lateral isolation trenches and filling the drain-select-level lateral isolation trenches with a dielectric material such as silicon oxide. Excess portions of the dielectric material can be removed from above the top surface of the topmost insulating layer 32T.

The exemplary in-process memory die comprises a memory array region 100 in which each layer within the alternating stack (32, 42) is present and in which a three-dimensional array of memory elements is to be subsequently formed, the contact region 200 which contains the stepped surfaces of the alternating stack (32, 42) and in which layer contact via structures contacting word lines are to be subsequently formed, and a peripheral region 400 in which the layers within the alternating stack (32, 42) are absent. The peripheral region 400 may comprise a kerf region through which the memory dies will be diced and an edge seal region. Openings may be formed through the in-process source-level material layers 110′ in the peripheral region 400 for formation of edge seal structures.

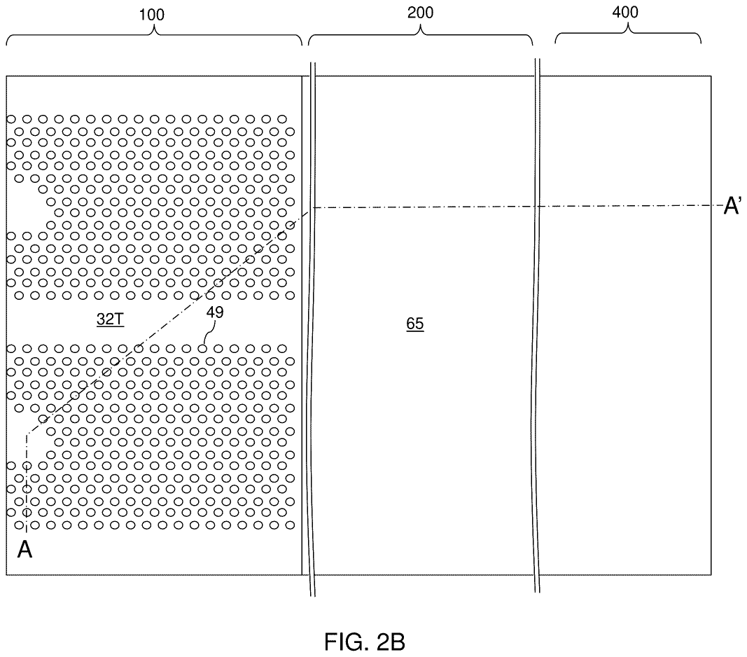

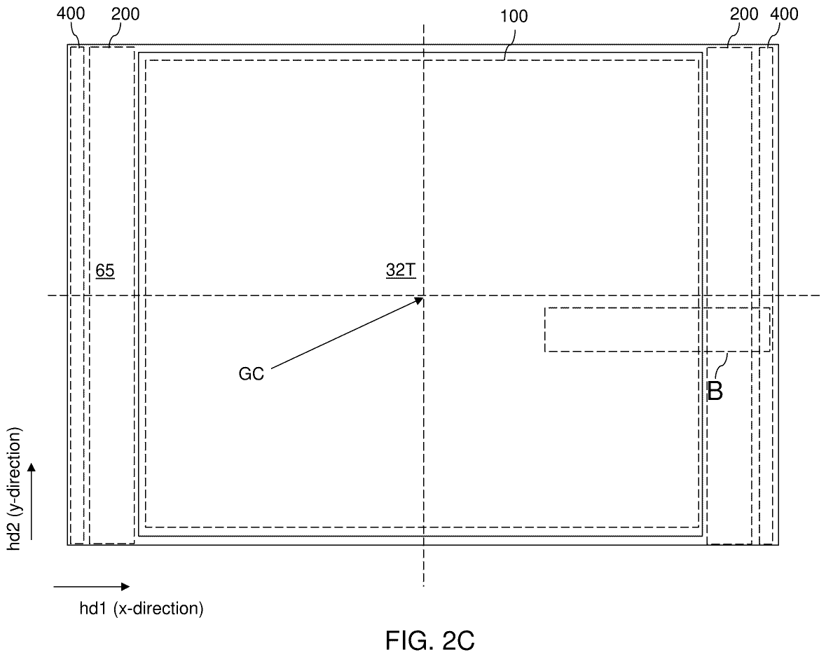

Referring to FIG. 2A-2C, various views of the exemplary in-process memory die are illustrated after formation of memory openings 49. FIG. 2C is a top-down view of the exemplary in-process memory die that illustrates an entire area of an in-process memory die. FIG. 2B is a top-down view of region B of the top-down view of the exemplary in-process memory die shown in FIG. 2C. FIG. 2A is a vertical cross-sectional view of the exemplary in-process memory die along the vertical plane A-A′ of FIG. 2B. The in-process memory die may have a rectangular shape in a plan view, such as the top-down view of FIG. 2C. The geometrical center GC of the in-process memory die is also illustrated in FIG. 2C. As used herein, a geometrical center of an element refers to a center of gravity of a hypothetical object occupying the same volume as the element and having a uniform density throughout.

Specifically, an etch mask layer (not shown) can be formed over the alternating stack (32, 42) and the retro-stepped dielectric material portion 65, and can be lithographically patterned to form various openings therein. An anisotropic etch process can be performed to transfer the pattern of the openings in the etch mask layer through the alternating stack (32, 42). Various openings can be formed through the alternating stack (32, 42). The various openings may comprise memory openings 49 that are formed in the memory array region 100 and support openings (not illustrated) that are formed in the contact region 200. Each of the memory openings 49 and the support openings can vertically extend through the alternating stack (32, 42) and into the in-process source-level material layers 110′. In one embodiment, bottom surfaces of the memory openings 49 and the support openings may be formed within the lower source-level semiconductor layer 112 or at an interface between the lower source-level semiconductor layer and the first memory-die proximal dielectric material layer 106.

The support openings may have a diameter in a range from 60 nm to 400 nm, such as from 120 nm to 300 nm, although lesser and greater thicknesses may be employed. The memory openings 49 may have a diameter in a range from 60 nm to 400 nm, such as from 120 nm to 300 nm, although lesser and greater thicknesses may be employed.

In one embodiment, the memory array region 100 may be laterally spaced apart from the contact region 200 along a first horizontal direction hd1. The memory openings 49 may comprise rows of memory openings 49 that are arranged along the first horizontal direction hd1 and laterally spaced apart along a second horizontal direction hd2 that is perpendicular to the first horizontal direction hd2. Multiple clusters of memory openings 49, each containing a respective two-dimensional periodic array of memory openings 49, may be formed in the memory array region 100. The clusters of memory openings 49 may be laterally spaced apart along the second horizontal direction hd2.

Sacrificial memory opening fill structures (not shown) can be formed in the memory openings 49. The sacrificial memory opening fill structures may comprise a carbon-based material (such as amorphous carbon or diamond-like carbon), a semiconductor material (such as amorphous silicon or polysilicon), a dielectric fill material (such as borosilicate glass or organosilicate glass), or an organic material. A dielectric fill material can be deposited in the support openings to form support pillar structures (not shown). The sacrificial memory opening fill structures can be subsequently removed to form cavities in the memory openings 49.

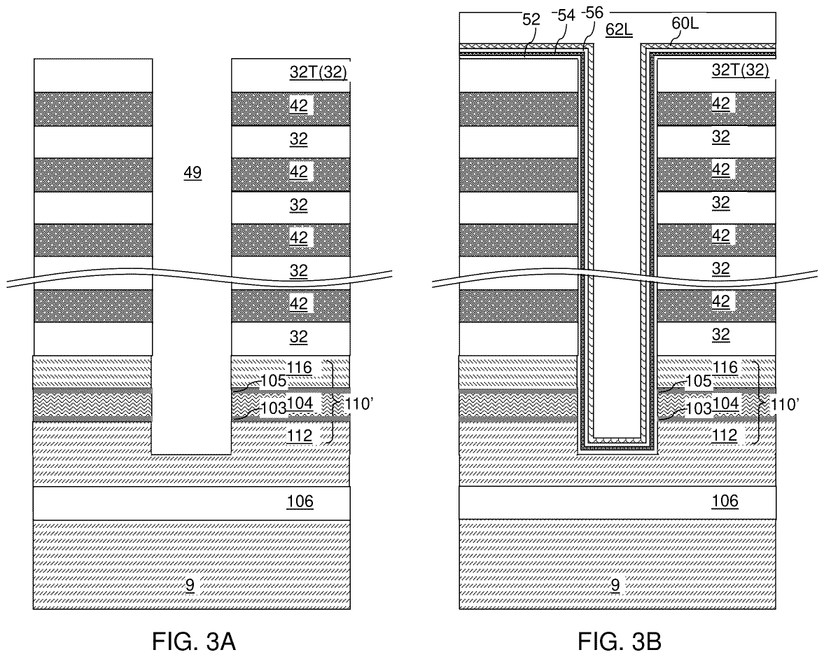

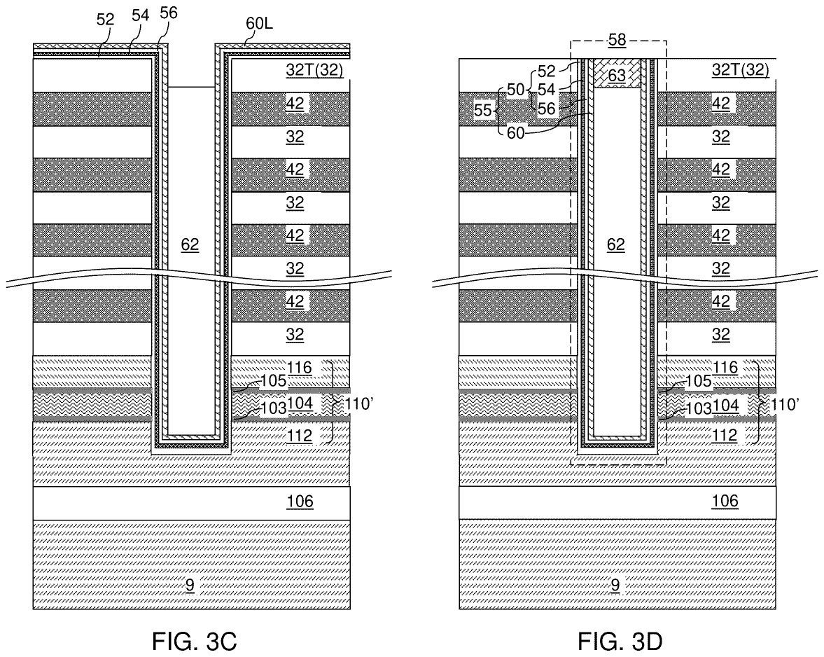

FIGS. 3A-3D are sequential vertical cross-sectional views of a memory opening 49 during formation of a NAND string (e.g., a dummy NAND string or a data storage NAND string) which is referred to below as a “memory opening fill structure” 58 according to an embodiment of the present disclosure.

Referring to FIG. 3A, a memory opening 49 is illustrated after the processing steps of FIGS. 2A-2C.

Referring to FIG. 3B, a layer stack including a memory material layer 54 can be conformally deposited. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride). In case the memory material layer 54 comprises a charge storage material, the optional dielectric liner 56 may comprise a tunneling dielectric layer.

A semiconductor channel material layer 60L can be deposited over the layer stack (52, 54, 56) by performing a conformal deposition process. If the semiconductor channel material layer 60L is doped, the semiconductor channel material layer 60L may have a doping of a first conductivity type, which may be p-type or n-type. In one embodiment, the first semiconductor material comprises a first doped silicon material having a doping of the first conductivity type. In an illustrative example, the atomic concentration of dopants of the first conductivity type in the semiconductor channel material layer 60L may be in a range from 1.0×10¹³/cm³ to 3.0×10¹⁷/cm³, such as 1.0×10¹⁴/cm³ to 3.0×10¹⁶/cm³, although lesser and greater atomic concentrations may also be employed. A dielectric core layer 62L comprising a dielectric fill material can be deposited in remaining volumes of the memory openings 49 and over the alternating stack (32, 42).

Referring to FIG. 3C, the dielectric core layer 62L can be vertically recessed such that each remaining portion of the dielectric core layer 62L has a top surface at, or about, the horizontal plane including the bottom surface of the topmost insulating layer 32T. Each remaining portion of the dielectric core layer 62L constitutes a dielectric core 62.

Referring to FIG. 3D, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5.0×10¹⁸/cm³ to 2.0×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel material layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel material layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination of a memory stack structure 55, a dielectric core 62, and a drain region 63 within a memory opening 49 constitutes a memory opening fill structure 58. Each memory opening fill structure 58 comprises a respective vertical stack of memory elements, which may comprise portions of the memory material layer 54 located at levels of the sacrificial material layers 42.

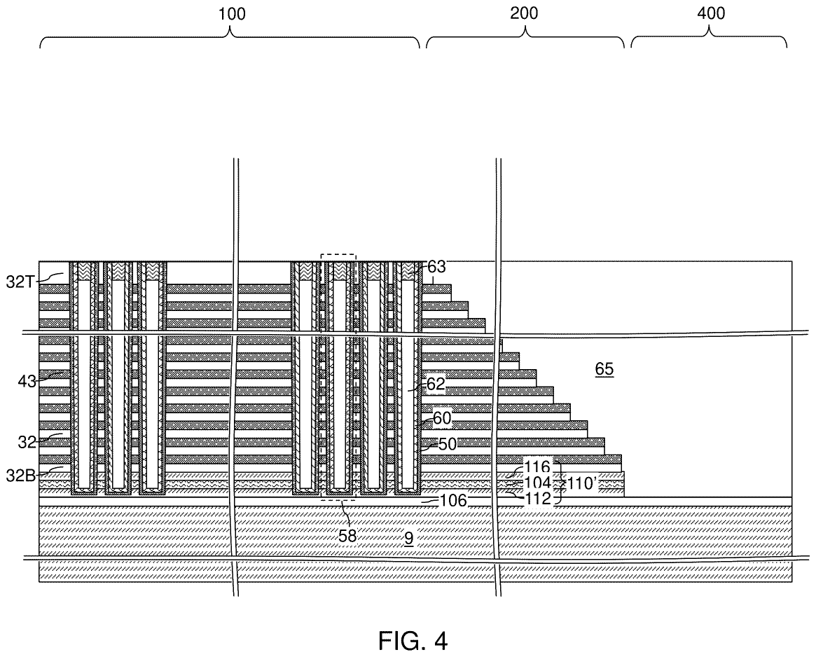

Referring to FIG. 4, the exemplary in-process memory die is illustrated after formation of memory opening fill structures 58 within the memory openings 49. Each of the memory opening fill structures 58 may comprise a memory stack structure 55, which comprises a memory film 50 and a vertical semiconductor channel 60. A combination of an alternating stack (32, 42) of insulating layers 32 and sacrificial material layers 42, memory openings 49 vertically extending through the alternating stack (32, 42), and memory opening fill structures 58 located in the memory openings 49 can be formed. Each of the memory opening fill structures 58 comprises a respective vertical stack of memory elements, such as portions of a memory material layer 54 located at levels of the sacrificial material layers 42.

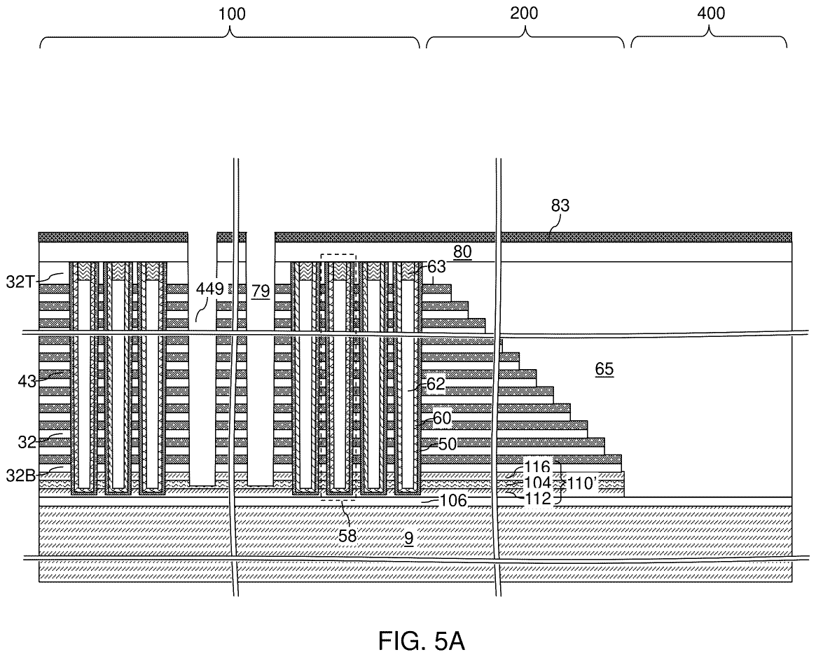

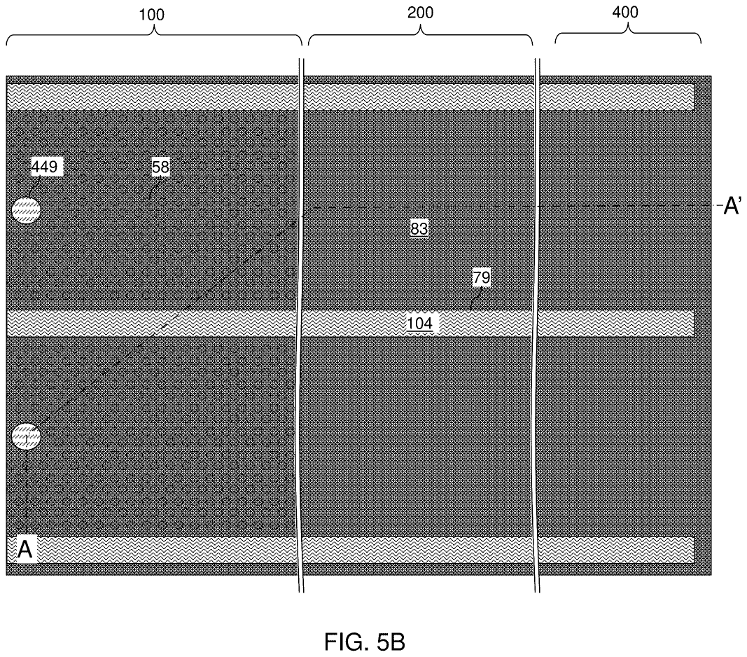

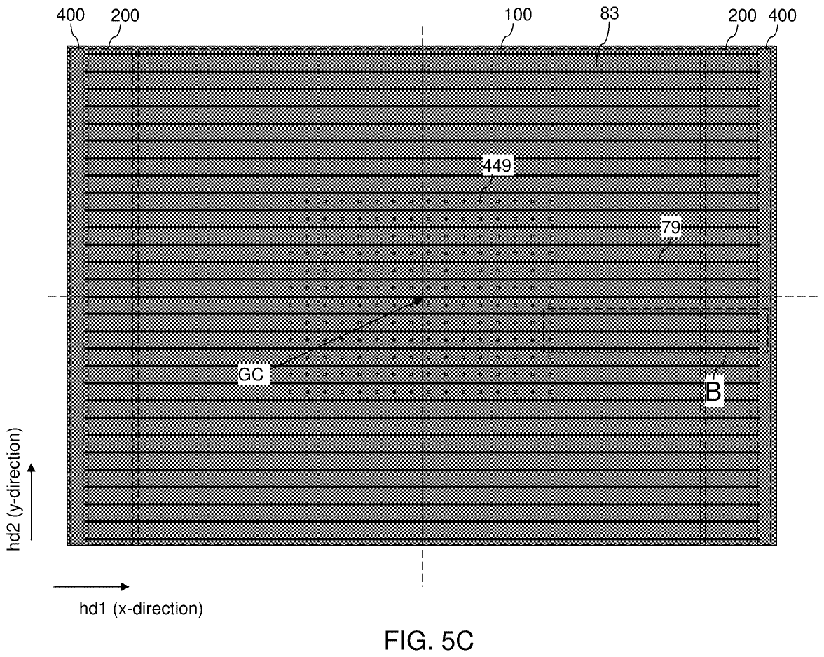

Referring to FIGS. 5A-5C, various views of the exemplary in-process memory die are illustrated after formation of a contact-level dielectric layer 80, a patterned hard mask layer 83, lateral isolation trenches 79, and through-stack openings 449. FIG. 5C is a top-down view of the exemplary in-process memory die that illustrates an entire area of an in-process memory die. FIG. 5B is a top-down view of region B of the top-down view of the exemplary in-process memory die shown in FIG. 5C. FIG. 5A is a vertical cross-sectional view of the exemplary in-process memory die along the vertical plane A-A′ of FIG. 5B.

Specifically, a dielectric material such as undoped silicate glass or a doped silicate glass can be deposited over the alternating stack (32, 42) to form a contact-level dielectric layer 80. The thickness of the contact-level dielectric layer 80 may be in a range from 100 nm to 600 nm, such as from 200 nm to 400 nm, although lesser and greater thicknesses may also be employed.

A hard mask material can be deposited over the contact-level dielectric layer 80, and can be patterned to form a patterned hard mask layer 83. The hard mask layer 83 may comprise any suitable hard mask material, such as titanium nitride, polysilicon, silicon nitride, etc. The pattern of the openings in the patterned hard mask layer 83 may comprise elongated openings that laterally extend along the first horizontal direction hd1 between neighboring clusters (e.g., memory blocks) of memory opening fill structures 58 through the memory array region 100 and a pair of contact regions 200, and discrete openings having circular horizontal cross-sectional shapes.

An anisotropic etch process can be performed to transfer the pattern of the openings in the patterned hard mask layer 83 through the contact-level dielectric layer 80, the alternating stack (32, 42), the retro-stepped dielectric material portion 65, and upper layers of the in-process source-level material layers 110′. Lateral isolation trenches 79 laterally extending along the first horizontal direction hd1 can be formed through the alternating stack (32, 42), the retro-stepped dielectric material portion 65, the contact-level dielectric layer 80, and upper layers of the in-process source-level material layers 110′ underneath the elongated openings in the patterned hard mask layer 83. Through-stack openings 449 can be formed through the alternating stack (32, 42), the retro-stepped dielectric material portion 65, the contact-level dielectric layer 80, and upper layers of the in-process source-level material layers 110′ underneath the discrete openings in the patterned hard mask layer 83. In one embodiment, bottom surfaces of the lateral isolation trenches 79 and the through-stack openings 449 may comprise surface segments of the source-level sacrificial layer 104. In one embodiment, the through-stack openings 449 may be arranged as a two-dimensional periodic array. In one embodiment, the through-stack openings 449 may be formed in a center region of the in-process memory die in a plan view. In one embodiment, peripheral regions of the in-process memory die may be free of any through-stack openings 449.

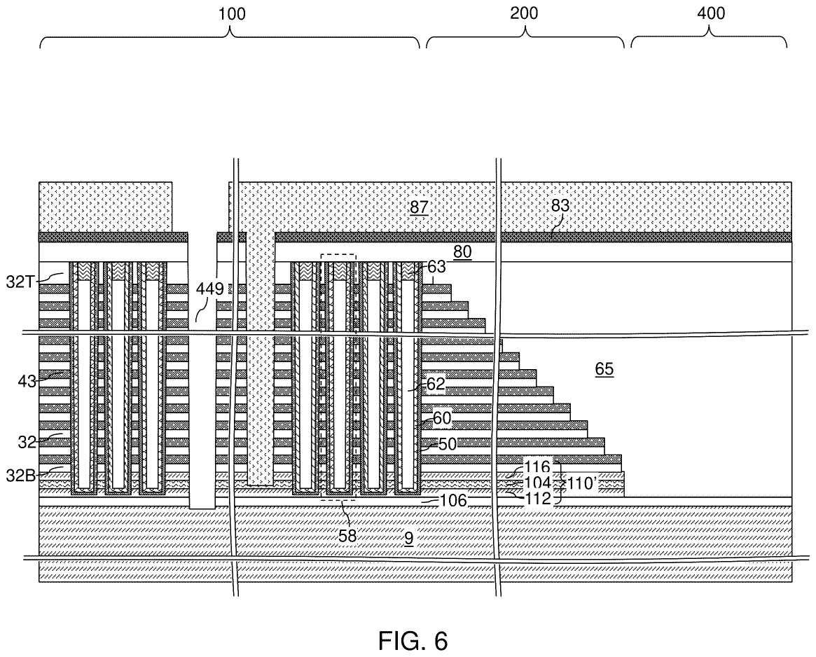

Referring to FIG. 6, a photoresist layer 87 can be applied over the exemplary in-process memory die, and can be lithographically patterned to form openings around the through-stack openings 449. The photoresist layer 87 can cover all areas of the lateral isolation trenches 79. An anisotropic etch process can be performed to vertically extend the through-stack openings 449 through the in-process source-level material layers 110′ and the first memory-die proximal dielectric material layer 106 and optionally into an upper portion of the carrier substrate 9. The photoresist layer 87 can be subsequently removed, for example, by ashing. The patterned hard mask layer 83 can be removed selectively to the contact-level dielectric layer, for example, by performing a wet etch process.

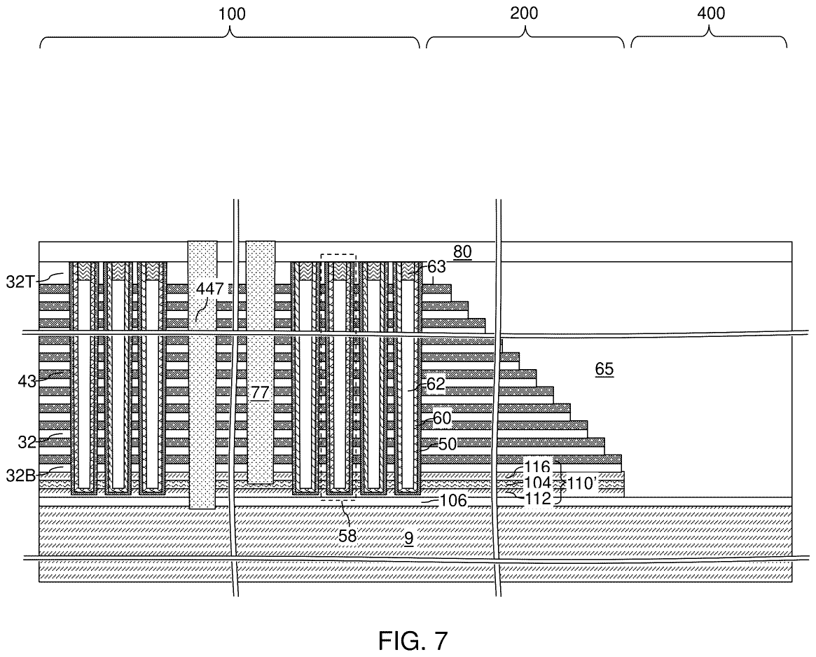

Referring to FIG. 7, a sacrificial fill material can be deposited in the lateral isolation trenches 79 and the through-stack openings 449. The sacrificial fill material may comprise a carbon-based material (such as amorphous carbon or diamond-like carbon), a semiconductor material (such as amorphous silicon or polysilicon), a dielectric fill material (such as borosilicate glass or organosilicate glass), or an organic material. Excess portions of the sacrificial fill material can be removed from above the horizontal plane including the top surface of the contact-level dielectric layer 80. Remaining portions of the sacrificial fill material filling the lateral isolation trenches 79 constitute sacrificial lateral isolation trench fill structures 77. Remaining portions of the sacrificial fill material filling the through-stack openings 449 constitute sacrificial through-stack opening fill structures 447.

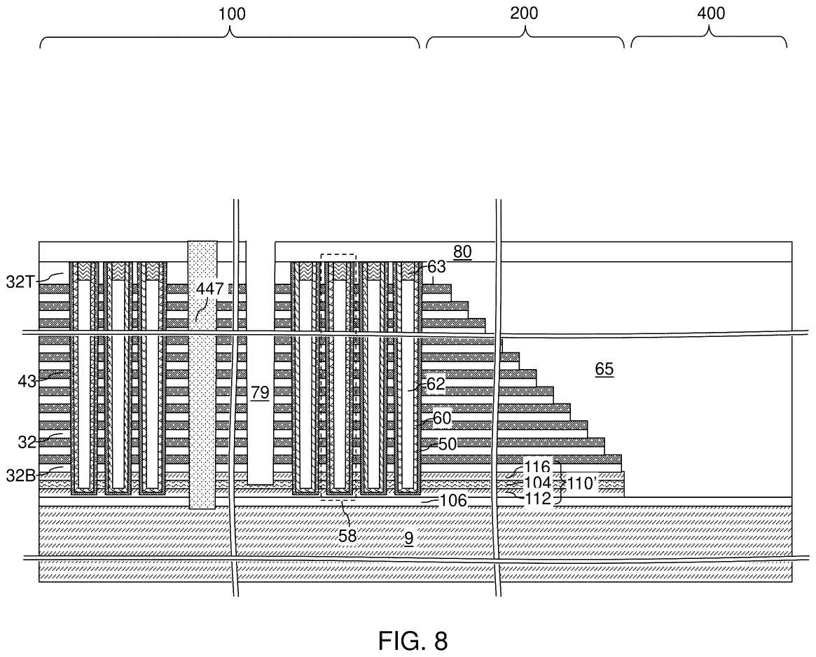

Referring to FIG. 8, a photoresist layer (not shown) can be applied over the contact-level dielectric layer 80, and can be lithographically patterned to cover the sacrificial through-stack opening fill structures 447 without covering the sacrificial lateral isolation trench fill structures 77. The sacrificial lateral isolation trench fill structures 77 can be removed selectively to the materials of the contact-level dielectric layer 80 and the alternating stack (32, 42) to form cavities within the volumes of the lateral isolation trenches 79 (i.e., to reopen the lateral isolation trenches 79).

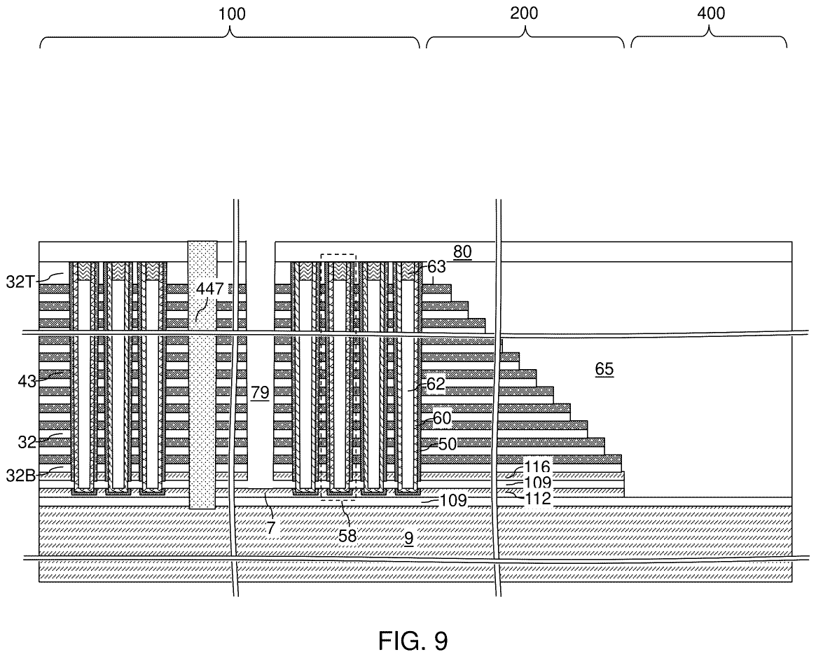

Referring to FIG. 9, an etch-stop spacer (not shown) may be optionally formed on sidewalls of the lateral isolation trenches by depositing and anisotropically etching an etch-stop barrier material, which may comprise silicon oxide or a dielectric metal oxide. An isotropic etch process can be performed to remove the source-level sacrificial layer 104 without removing the contact-level dielectric layer 80, the retro-stepped dielectric material portion 65, the lower source-level semiconductor layer 112, the upper source-level semiconductor layer 116, the upper sacrificial liner 105 (if present), and the lower sacrificial liner 103 (if present). For example, if the source-level sacrificial layer 104 includes undoped amorphous silicon or a silicon-germanium alloy, a wet etch process using hot trimethyl-2 hydroxyethyl ammonium hydroxide (“hot TMY”) or tetramethyl ammonium hydroxide (TMAH) may be used to remove the source-level sacrificial layer 104 selectively to the alternating stack (32, 42), the contact-level dielectric layer 80, the retro-stepped dielectric material portion 65, the lower source-level semiconductor layer 112, and the upper source-level semiconductor layer 116. A source cavity 109 is formed in the volume from which the source-level sacrificial layer 104 is removed.

Wet etch chemicals such as hot TMY and TMAH can etch an undoped semiconductor material of the source-level sacrificial layer 104 selectively to doped semiconductor materials such as the p-doped semiconductor material and/or the n-doped semiconductor material of the upper source-level semiconductor layer 116 and the lower source-level semiconductor layer 112. Thus, use of selective wet etch chemicals such as hot TMY and TMAH for the wet etch process that forms the source cavity 109 provides a large process window against etch depth variation during formation of the lateral isolation trenches 79. Specifically, even if sidewalls of the upper source-level semiconductor layer 116 are physically exposed or even if a surface of the lower source-level semiconductor layer 112 is physically exposed upon formation of the source cavity 109, collateral etching of the upper source-level semiconductor layer 116 and/or the lower source-level semiconductor layer 112 is minimal, and the structural change to the exemplary in-process memory die caused by accidental physical exposure of the surfaces of the upper source-level semiconductor layer 116 and/or the lower source-level semiconductor layer 112 during manufacturing steps do not result in device failures. Each of the memory opening fill structures 58 is physically exposed to the source cavity 109. Specifically, each of the memory opening fill structures 58 includes a sidewall that is physically exposed to the source cavity 109.

A sequence of isotropic etchants, such as wet etchants, may be applied to the physically exposed portions of the memory films 50 to sequentially etch the various component layers of the memory films 50 from outside to inside, and to physically expose cylindrical surfaces of the vertical semiconductor channels 60 at the level of the source cavity 109. The upper sacrificial liner 105 (if present) and the lower sacrificial liner 103 (if present) may be collaterally etched during removal of the portions of the memory films 50 located at the level of the source cavity 109. The source cavity 109 may be expanded in volume by removal of the portions of the memory films 50 at the level of the source cavity 109 and the upper and lower sacrificial liners. A top surface of the lower source-level semiconductor layer 112 and a bottom surface of the upper source-level semiconductor layer 116 may be physically exposed to the source cavity 109. The source cavity 109 is formed by isotropically etching the source-level sacrificial layer 104 and a bottom portion of each of the memory films 50 selectively to at least one source-level semiconductor layer (such as the lower source-level semiconductor layer 112 and the upper source-level semiconductor layer 116) and the vertical semiconductor channels 60.

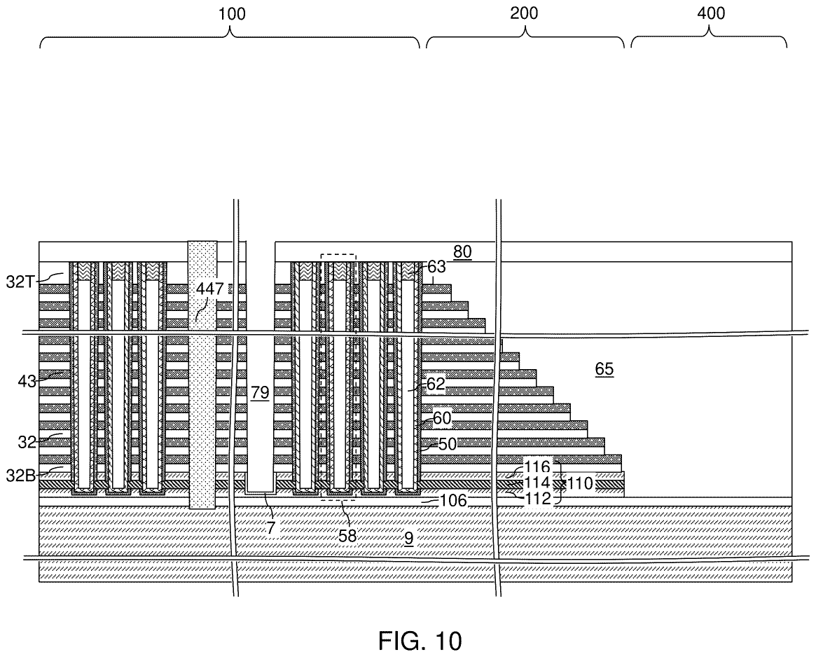

Referring to FIG. 10, a semiconductor material having a doping of the second conductivity type may be deposited on the physically exposed semiconductor surfaces around the source cavity 109. The physically exposed semiconductor surfaces include bottom portions of outer sidewalls of the vertical semiconductor channels 60 and a horizontal surface of the at least one source-level semiconductor layer (such as a bottom surface of the upper source-level semiconductor layer 116 and/or a top surface of the lower source-level semiconductor layer 112). For example, the physically exposed semiconductor surfaces may include the bottom portions of outer sidewalls of the vertical semiconductor channels 60, the top horizontal surface of the lower source-level semiconductor layer 112, and the bottom surface of the upper source-level semiconductor layer 116.

In one embodiment, the doped semiconductor material of the second conductivity type may be deposited on the physically exposed semiconductor surfaces around the source cavity 109 by a selective semiconductor deposition process. Optionally, one or more etch back processes may be used in combination with a plurality of selective or non-selective deposition processes to provide a seamless and/or voidless source contact layer 114. Alternatively, the source contact layer 114 can be formed by performing a non-selective doped semiconductor material deposition process such as a low-pressure chemical vapor deposition process. In this case, an etch-back process can be performed to remove portions of the deposited doped semiconductor material that are deposited in the lateral isolation trenches 79 or above the contact-level dielectric layer 80. The atomic concentration of the dopants of the second conductivity type in the deposited semiconductor material may be in a range from 1.0×10²⁰/cm³ to 2.0×10²¹/cm³, such as from 2.0×10²⁰/cm³ to 8.0×10²⁰/cm³.

The layer stack including the lower source-level semiconductor layer 112, the source contact layer 114, and the upper source-level semiconductor layer 116 constitutes a source layer 110, which replaces the in-process source-level material layers 110′. The source layer 110 contacts a sidewall surface segment of each of the vertical semiconductor channels 60. An oxidation process can be performed to convert physically exposed portions of the semiconductor material layer around bottom portions of the lateral isolation trenches 79. A semiconductor oxide liner 7, such as a silicon oxide liner, can be formed at the bottom of each lateral isolation trench 79.

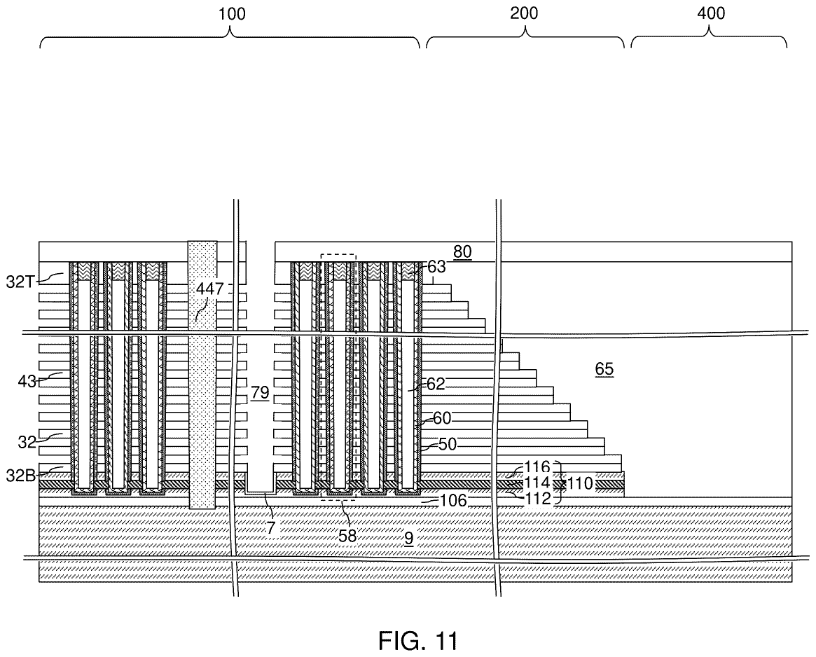

Referring to FIG. 11, an isotropic etch process can be performed to remove the sacrificial material layers 42 selectively to the insulating layers 32, the semiconductor oxide liners 7, the memory opening fill structures 58, and the source layer 110. Laterally-extending cavities 43 can be formed in volumes from which the sacrificial material layers 42 are removed. Sidewall surface segments of the memory opening fill structures 58 can be physically exposed to the laterally-extending cavities 43. In an illustrative example, if the sacrificial material layers 42 comprise silicon nitride, the isotropic etch process may comprise a wet etch process employing hot phosphoric acid, which is a process in which the exemplary in-process memory die is immersed in phosphoric acid at or near the boiling point of the phosphoric acid. A suitable clean process may be performed as needed. In summary, the laterally-extending cavities 43 can be formed by removing the sacrificial material layers 42 selectively to the insulating layers 32 and the memory opening fill structures 58.

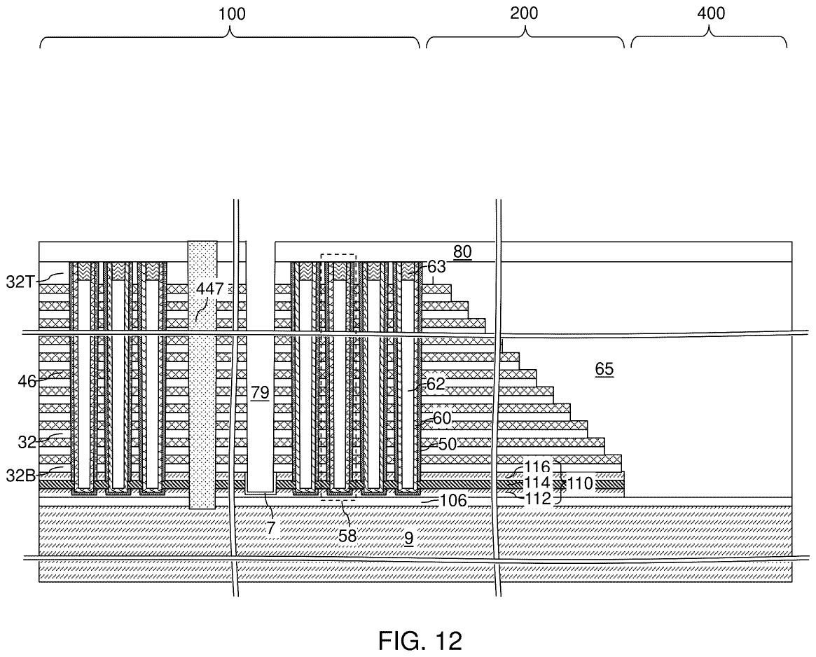

Referring to FIG. 12, a backside blocking dielectric layer (not shown) may be optionally deposited in the laterally-extending cavities 43. The backside blocking dielectric layer, if employed, includes, and/or consists essentially of, a dielectric metal oxide material. At least one electrically conductive material can be conformally deposited in the laterally-extending cavities 43. The at least one electrically conductive material may comprise a combination of a metallic nitride barrier material and a metal fill material. For example, the metallic nitride barrier material may comprise TiN, TaN, WN, or MoN, and the metal fill material may comprise W, Ru, Mo, Co, etc.

An anisotropic etch process can be performed to remove portions of the at least one electrically conductive material and optionally the backside blocking dielectric layer from inside the volumes of the lateral isolation trenches 79 and from above the contact-level dielectric layer 80. Each contiguous remaining portion of the at least one electrically conductive material located within a volume of a respective laterally-extending cavity 43 constitutes an electrically conductive layer 46. Alternating stacks (32, 46) of insulating layers 32 and electrically conductive layers 46 is formed between each neighboring pair of lateral isolation trenches 79. Thus, the alternating stacks (32, 46) of insulating layers 32 and electrically conductive layers 46 can be laterally spaced apart from each other along the second horizontal direction hd2 by the lateral isolation trenches 79.

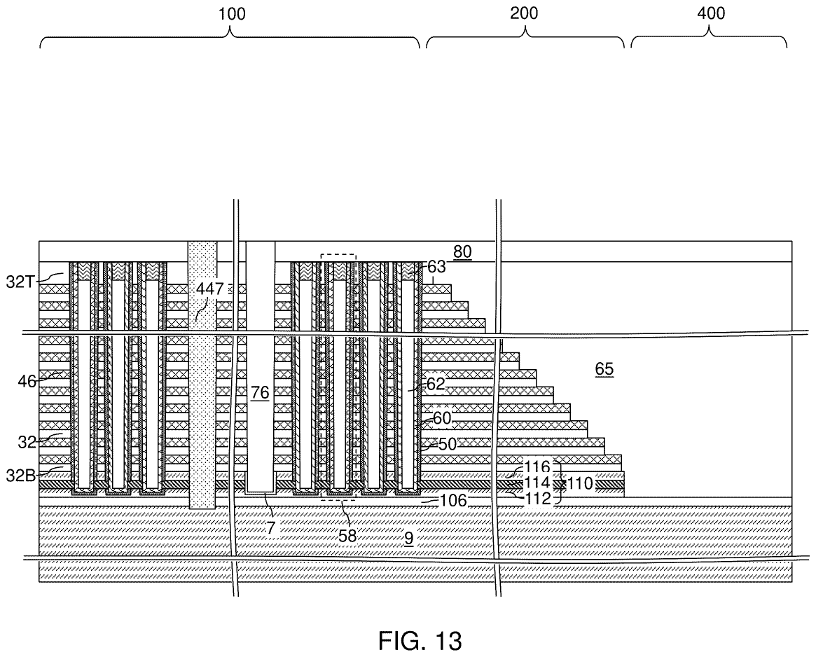

Referring to FIG. 13, an insulating fill material may be conformally deposited in the lateral isolation trenches 79. Excess portions of the insulating fill material may be removed from above the contact-level dielectric layer 80, for example, by a recess etch process.

Each remaining portion of the insulating fill material that fills a respective lateral isolation trench 79 constitutes a lateral isolation trench fill structure 76. Alternatively, each lateral isolation trench fill structure 76 may comprise a combination of a tubular insulating spacer (not expressly shown) and a conductive connection via structure (not expressly shown) that is laterally surrounded by the tubular insulating spacer.

In summary, a lateral isolation trench fill structure 76 having insulating sidewalls can be formed within each lateral isolation trench 79. Each lateral isolation trench fill structure 76 vertically extends from a bottommost surface of an alternating stack (32, 46) to another horizontal plane including a topmost surface of the alternating stack (32, 46).

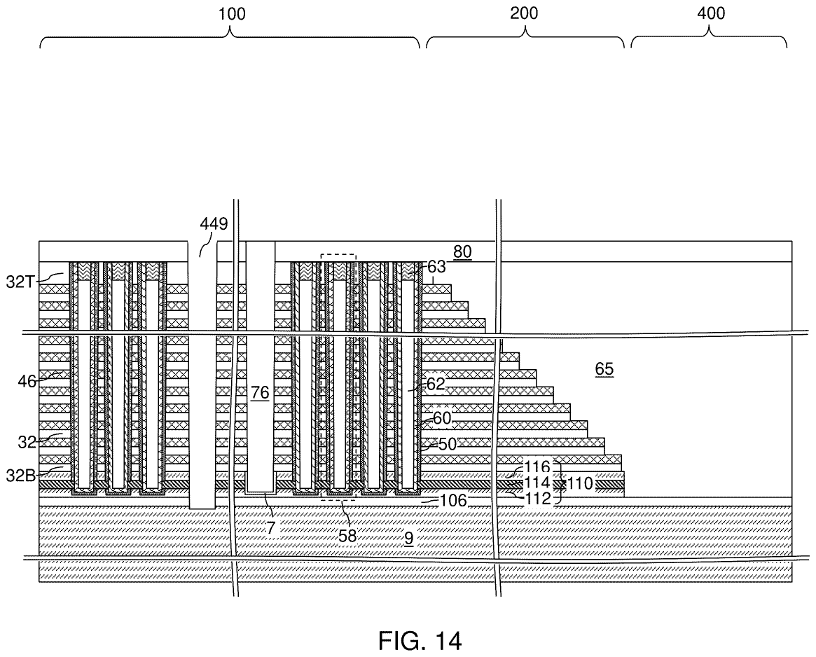

Referring to FIG. 14, a selective etch process can be performed to remove the sacrificial through-stack opening fill structures 447 selectively to the materials of the contact-level dielectric layer 80 and the alternating stacks (32, 42). Cavities are formed in the volumes of the through-stack openings 449.

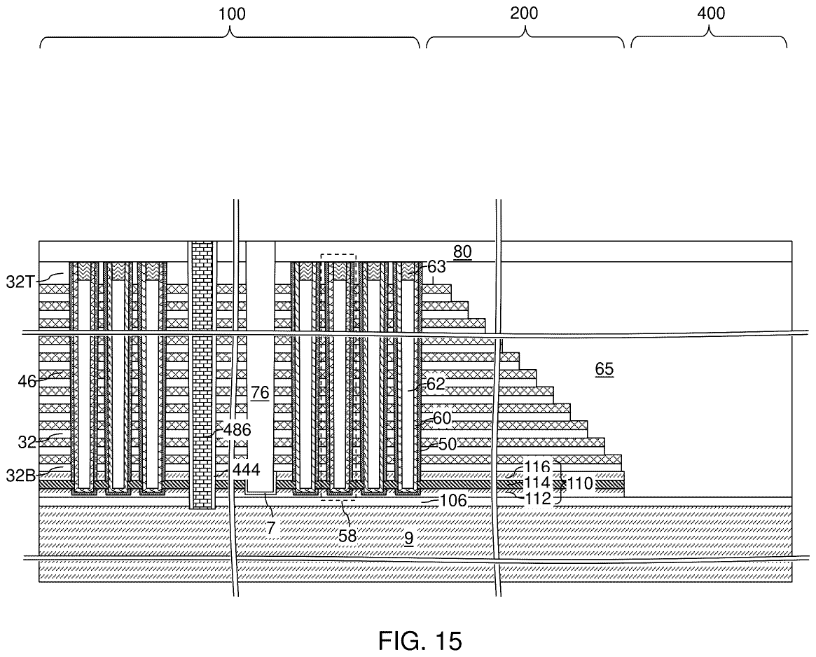

Referring to FIG. 15, a dielectric material, such as silicon oxide, can be conformally deposited in peripheral portions of the through-stack openings 449. An anisotropic etch process can be performed to remove horizontally-extending portions of the deposited dielectric material. Each remaining tubular portion of the deposited dielectric material located in peripheral regions of the through-stack openings 449 constitutes a tubular dielectric spacer 444. The lateral thickness of each tubular dielectric spacer 444 (as measured between an inner sidewall and an outer sidewall) may be in a range from 30 nm to 100 nm, although lesser and greater thicknesses may also be employed.

At least one electrically conductive material, can be deposited in center regions of the through-stack openings 449. Excess portions of the at least one conductive material can be removed from above the horizontal plane including the top surface of the contact-level dielectric layer 80 by performing a planarization process such as a chemical mechanical planarization process. Each remaining portion of the at least one conductive material that remains in a respective through-stack opening 449 comprises a through-stack via structure 446.

The through-stack via structures 446 are formed in a center region of the in-process memory die. As used herein, the center region is defined as a volume within the in-process memory die that is more proximal to the geometrical center GC of the in-process memory die than to a periphery of the in-process memory die. The periphery is defined by the outer boundary of the in-process memory die in a plan view along a vertical direction.

In one embodiment, at least one of the vertically-extending openings 449 in the alternating stacks (32, 46) is entirely laterally surrounded by a respective one of the alternating stacks (32, 46). In one embodiment, the entirety of at least one of the vertically-extending openings 449 may be located within the area of a respective one of the alternating stacks (32, 46) in the plan view. In one embodiment, at least one of the through-stack via structures 446 is located within a respective one of the vertically-extending openings 449, and is laterally spaced from a sidewall of the respective one of the vertically-extending opening 449 by a respective tubular dielectric spacer 444.

In one embodiment, sidewalls of the through-stack openings 449 may be tapered such that each through-stack opening 449 has a greater lateral dimension at its top than at its bottom. In one embodiment, sidewalls of the through-stack via structures 446 are tapered relative to a vertical direction such that each of the through-stack via structures 446 has a respective variable horizontal cross-sectional area that increases with a vertical distance from the carrier substrate 9.

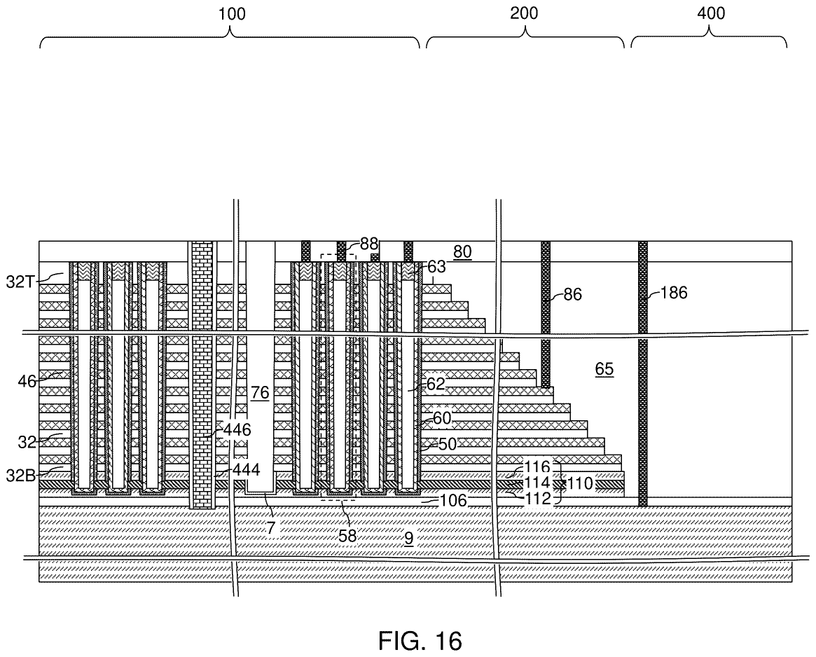

Referring to FIG. 16, a photoresist layer (not shown) can be applied over the contact-level dielectric layer 80, and can be lithographically patterned to form openings over each of the memory opening fill structures 58 over the horizontally-extending surfaces of the stepped surfaces in the contact region. An anisotropic etch process can be performed to transfer the pattern of the openings in the photoresist layer through the contact-level dielectric layer 80 and the retro-stepped dielectric material portion 65. Drain contact via cavities can be formed through the contact-level dielectric layer 80 over the memory opening fill structures 58. Layer contact via cavities can be formed through the contact-level dielectric layer 80 and the retro-stepped dielectric material portion 65 on a top surface of a respective one of the electrically conductive layers 46. Peripheral edge seal cavities and peripheral connection via cavities can be formed in the peripheral region 400. The photoresist layer can be subsequently removed, for example, by ashing.

At least one conductive material, such as a combination of a metallic barrier material and a metal fill material, can be deposited in the drain contact via cavities, the layer contact via cavities, and peripheral connection via cavities. Excess portions of the at least one conductive material can be removed from above the horizontal plane including the top surface of the contact-level dielectric layer 80 by a planarization process, which may employ a recess etch process and/or a chemical mechanical polishing process. Remaining portions of the at least one conductive material that fill the drain contact via cavities constitute drain contact via structures 88 contacting a top surface of a respective one of the drain regions 63. Remaining portions of the at least one conductive material that fill the layer contact via cavities constitute layer contact via structures 86 contacting a top surface of a respective one of the electrically conductive layers 46. Remaining portions of the at least one conductive material that fill the respective peripheral connection via cavities constitute peripheral connection via structures 186.

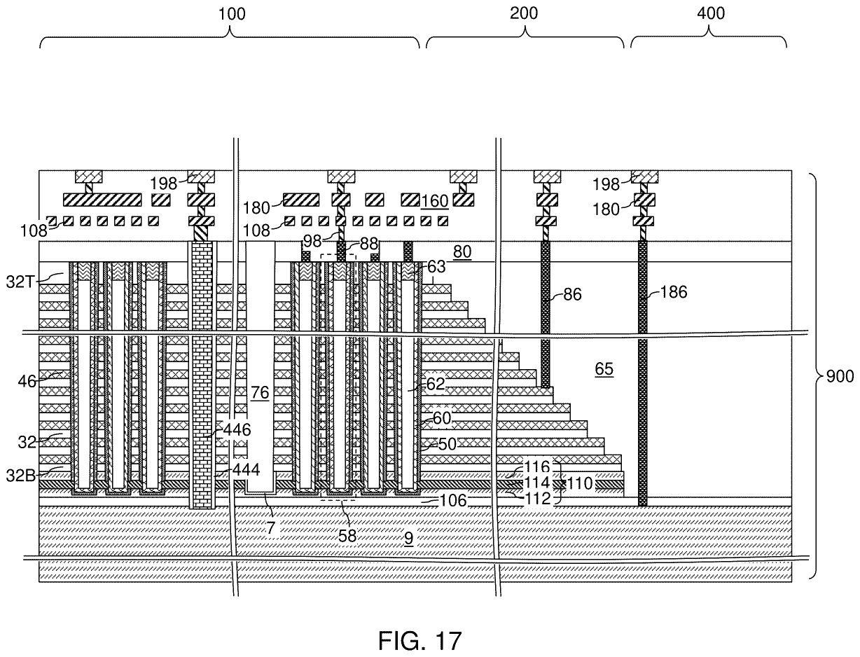

Referring to FIG. 17, additional dielectric material layers embedding interconnect structures can be formed over the contact-level dielectric layer 80. The interconnect structures may comprise an electrically conductive material, such as a metal, a metal alloy, a metal silicide, or a conductive metal nitride. The additional dielectric material layers are herein referred to as memory-die front dielectric material layers 160. The interconnect structures are herein referred to as memory-die front metal interconnect structures (98, 108, 180). The memory-die front metal interconnect structures (98, 108, 180) may include bit lines 108 that laterally extend along the second horizontal direction hd2, bit-line-connection via structures 98 that connect the drain contact via structures 88 with the bit lines 108, and additional interconnect structures 180 which include various types of metal via structures and various types of metal lines.

Memory-die front bonding structures 198 configured for metal-to-metal bonding can be formed in the topmost dielectric layer of the memory-die front dielectric material layers 160. Metal-to-metal bonding involves direct attachment of contacting metal surfaces to each other without use of any intermediate material. As used herein, “metal-to-metal bonding” refers to the process of directly joining metal surfaces without any intervening adhesive or bonding layer. An exemplary metal-to-metal bonding process comprises a copper-to-copper bonding in which mating copper surfaces are pushed against each other at an elevated temperature, which may be in a range from 200 degrees Celsius to 400 degrees Celsius. In one embodiment, the memory-die front bonding structures 198 may have physically exposed copper surfaces.

The exemplary in-process memory die formation is completed to form a memory die 900, i.e., the final device structure derived from the exemplary in-process memory die. In one embodiment, a two-dimensional array of memory dies 900 may be formed on the same carrier substrate 9. For example, the carrier substrate 9 may comprise a commercially available silicon wafer, and the two-dimensional array of memory dies 900 may comprise a periodic rectangular array of memory dies 900 comprising a respective portion of the silicon wafer and the overlying device layers.

In summary, a plurality of memory dies 900 can be provided. Each of the plurality of memory dies 900 may comprise: an alternating stack (32, 46) of insulating layers 32 and electrically conductive layers 46 that alternate along a vertical direction; a two-dimensional array of memory stack structures 55 each containing a respective vertical semiconductor channel 60 and respective vertical stack of memory elements (comprising portions of the memory material layer 54); and through-stack via structures 446 vertically extending at least from a horizontal plane including a bottommost surface of the alternating stack (32, 46) to another horizontal plane including a topmost surface of the alternating stack (32, 46).

In one embodiment, each memory die 900 may comprise a respective carrier substrate 9, a respective alternating stack (32, 46) of respective insulating layers 32 and respective electrically conductive layers 46, respective memory opening fill structures 58 vertically extending through the respective alternating stack (32, 46) and comprising a respective vertical stack of respective memory elements (which may comprise portions of memory material layers 54 located at levels of the electrically conductive layers 46), an optional respective memory-die dielectric material portion (such as a retro-stepped dielectric material portion 65) laterally offset from the respective alternating stack (32, 46), and respective memory-die front dielectric material layers 160 embedding respective memory-die front metal interconnect structures (98, 108, 180) and respective memory-die front bonding structures 198.

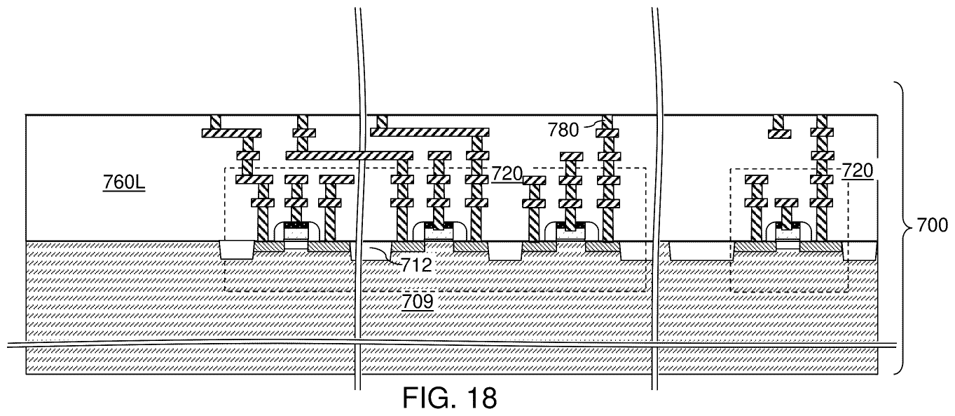

Referring to FIG. 18, an exemplary in-process memory-controller die 700 (e.g., logic die) is illustrated. The exemplary in-process memory-controller die 700 may be provided within a unit area in a substrate, such as a semiconductor wafer (e.g., a silicon wafer) including a two-dimensional array of memory-controller dies 700. The exemplary in-process memory-controller die 700 comprises a semiconductor substrate, which is herein referred to as a controller-die substrate 709. The controller-die substrate 709 may comprise a portion of a silicon wafer. Shallow trench isolation structures 712 can be formed in an upper portion of the controller-die substrate 709. A memory controller circuit 720, which is also referred to as a memory controller circuit or a driver circuit, can be formed on and/or over the top surface of the controller-die substrate 709.

The memory controller circuit 720 is configured to control operation of the memory array within the memory die 900. For example, the memory controller circuit 720 may comprise word line drivers configured to drive word lines, which are a subset of the electrically conductive layers 46 within the alternating stacks (32, 46). The memory controller circuit 720 may comprise bit line drivers configured to drive the bit lines 108 in the memory die 900. For example, as described with reference to the memory die 900, the bit lines 108 of a memory die 900 may be electrically connected to first ends (i.e., the ends that are connected to the drain regions 63) of a respective subset of the memory stack structures 55. The memory controller circuit 720 may comprise source line drivers configured to drive one or more source layers to be subsequently formed on the memory die 900 after removal of the carrier substrate 9. The memory controller circuit 720 may also comprise input/output control circuits configured to receive input data from, or to transmit output data to, at least one conductive pad (which may be a bonding structure) to be subsequently formed on the through-stack via structures 446 after removal of the carrier substrate 9. Generally, the memory controller circuit 720 may comprise any electronic circuit configured to manage data flow, handle read and write operations, ensure data integrity through error correction, perform wear leveling to extend memory lifespan, and/or support communication protocols for interfacing with external devices and systems for the three-dimensional memory array in the memory die 900.

Controller-die front metal interconnect structures 780 embedded within controller-die front dielectric material layers 760 can be formed over the memory controller circuit 720. Specifically, a subset of the controller-die front metal interconnect structures 780 embedded within a subset of the controller-die front dielectric material layers 760 can be formed. The subset of the controller-die front dielectric material layers 760 is herein referred to as lower controller-die front dielectric material layers 760L. In the illustrated example in FIG. 18, the lower controller-die front dielectric material layers 760L comprise four via-level dielectric material layers and four line-level dielectric material layers. Generally, the total number of line levels within the lower controller-die front dielectric material layers 760L may be in a range from 1 to 12.

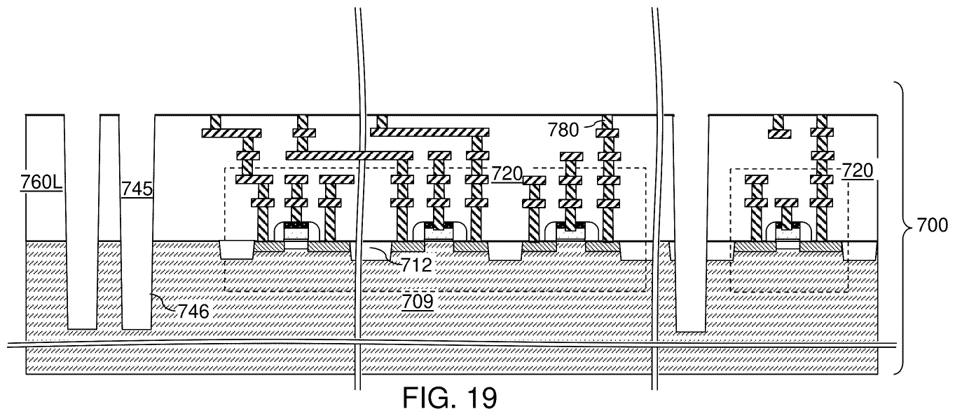

Referring to FIG. 19, an etch mask layer (not shown) may be formed over the lower controller-die front dielectric material layers 760L, and can be lithographically patterned to form various openings in areas in which the subset of the controller-die front metal interconnect structures 780 is not present. An anisotropic etch process can be performed to etch unmasked portions of the lower controller-die front dielectric material layers 760L and unmasked upper portions of the controller-die substrate 709. Through-substrate via cavities 745 are formed within the volumes from which the materials of the lower controller-die front dielectric material layers 760L and the controller-die substrate 709 are etched. Each through-substrate via cavity 745 comprises a straight or substantially-straight sidewall having a top periphery within a horizontal plane including a top surface of one of the lower controller-die front dielectric material layers 760L and top surfaces of a subset of the controller-die front metal interconnect structures 780, and having a bottom periphery located within the controller-die substrate 709.

The top periphery of each through-substrate via cavity 745 may have a greater lateral dimension than the bottom periphery of the same through-substrate via cavity 745. In an illustrative example, the lateral dimension (such as a diameter) of the top periphery of a through-substrate via cavity 745 may be in a range from 5 microns to 60 microns, such as from 10 microns to 40 microns, although lesser or greater lateral dimensions may also be employed. The vertical extent of each through-substrate via cavity 745 may be in a range from 5 microns to 100 microns, such as from 10 microns to 50 microns, although lesser or greater vertical extents may also be employed. The etch mask layer may be subsequently removed, for example, by ashing.

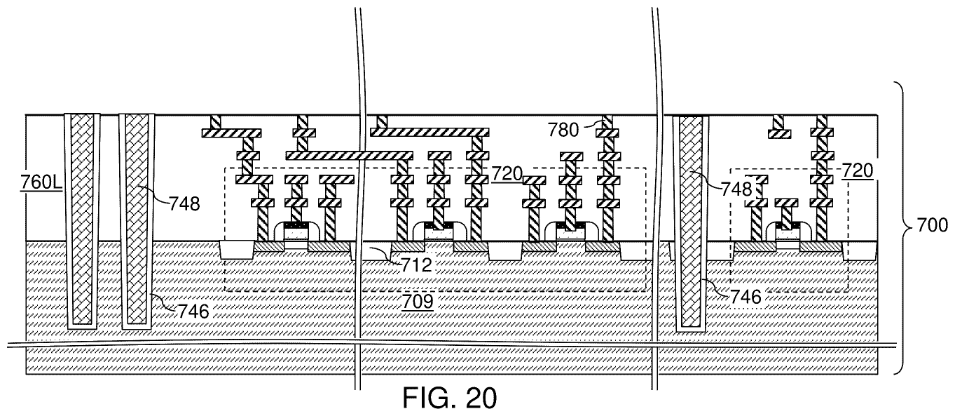

Referring to FIG. 20, a dielectric isolation material, such as undoped silicate glass (i.e., silicon oxide) or a doped silicate glass, may be conformally deposited in peripheral regions of the through-substrate via cavities 745 and over the lower controller-die front dielectric material layers 760L to form of a dielectric isolation material layer. The thickness of the dielectric isolation material layer may be in a range from 10 nm to 300 nm, although lesser or greater thicknesses may also be employed. At least one electrically conductive material, such as a combination of a conductive metallic nitride (e.g., TiN, WN, TaN or MoN) material and a metal fill material (such as W, Cu, Co, Ru, Mo, etc.) may be deposited in remaining volumes of the through-substrate via cavities 745 and over a horizontally-extending portion of the dielectric isolation material layer.

A planarization process, such as a chemical mechanical polishing process and/or a recess etch process, can be performed to remove a horizontally-extending portion of the at least one electrically conductive material. Each remaining portion of the at least one electrically conductive material constitutes a respective through-substrate via structure 748. Each remaining portion of the dielectric isolation material layer that laterally surrounds a respective one of the through-substrate via structures 748 comprises a dielectric isolation liner 746. In one embodiment, top surfaces of the through-substrate via structures 748 and the dielectric isolation liners 746 may be formed within a horizontal plane including a top surface of one of the lower controller-die front dielectric material layers 760L.

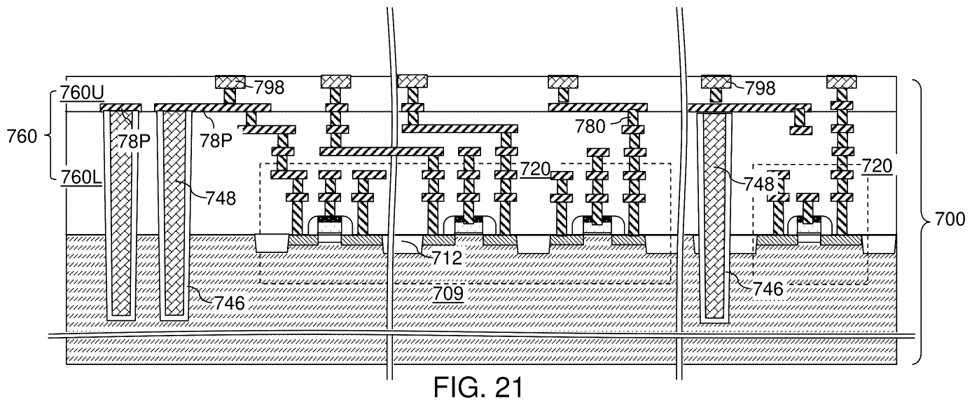

Referring to FIG. 21, an additional subset of the controller-die front metal interconnect structures 780 embedded within an additional subset of the controller-die front dielectric material layers 760 can be formed. The additional subset of the controller-die front dielectric material layers 760 is herein referred to as upper controller-die front dielectric material layers 760U. In the illustrated example in FIG. 21, the upper controller-die front dielectric material layers 760U comprise a line-level dielectric material layer and a via-level dielectric material layer. Generally, the total number of line levels within the upper controller-die front dielectric material layers 760U may be in a range from 1 to 12.

In one embodiment, a through-substrate via structure 748 can be contacted by a controller-die front metal interconnect structure 780, which can be employed to provide electrical connection between the through-substrate via structure 748 and a respective electrical node of the memory controller circuit 720. In one embodiment, the controller-die front metal interconnect structure 780 may comprise an electrically conductive pad 78P having a same thickness and a same material composition as metal line structures embedded within the upper controller-die front dielectric material layers 760U. For example, the electrically conductive pad 78P may comprise one or more electrically conductive layers, such as metal (e.g., W, Ti, Ta, Mo, etc.), metallic metal nitride (e.g., TiN, TaN, WN or MoN) and/or metal silicide (e.g., titanium, cobalt or molybdenum silicide). The electrically conductive pad 78P may contact the top of the through-substrate via structure 748, and electrically connect the through-substrate via structure 748 to respective metal via structure, which is one of the controller-die front metal interconnect structures 780.

Bonding structures configured for metal-to-metal bonding can be formed in the topmost layer among the controller-die front dielectric material layers 760. These bonding structures are herein referred to as controller-die front bonding structures 798. The controller-die front bonding structures 798 can be electrically connected to a respective electrical node of the memory controller circuit 720, and can be arranged in a pattern that is a mirror image pattern of the memory-die front bonding structures 198 of the memory die 900. In one embodiment, each memory-controller die 700 may be provided within a unit die area in a semiconductor wafer including a two-dimensional array of memory-controller dies 700.

A plurality of memory-controller dies 700 may be provided. Each memory-controller die 700 comprises a respective controller-die substrate 709, a respective memory controller circuit 720 configured to control operation of a memory die 900 and including a respective set of semiconductor devices located on a front surface of the respective controller-die substrate 709; and respective controller-die front dielectric material layers 760 embedding respective controller-die front metal interconnect structures 780 and located on the respective set of semiconductor devices; respective controller-die front bonding structures 798 that are embedded within the controller-die front dielectric material layers 760.

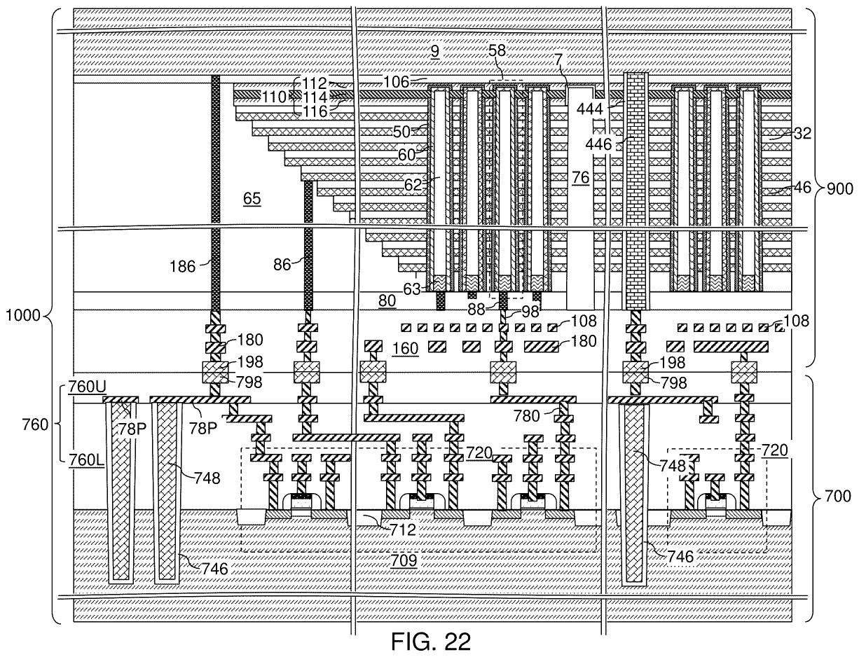

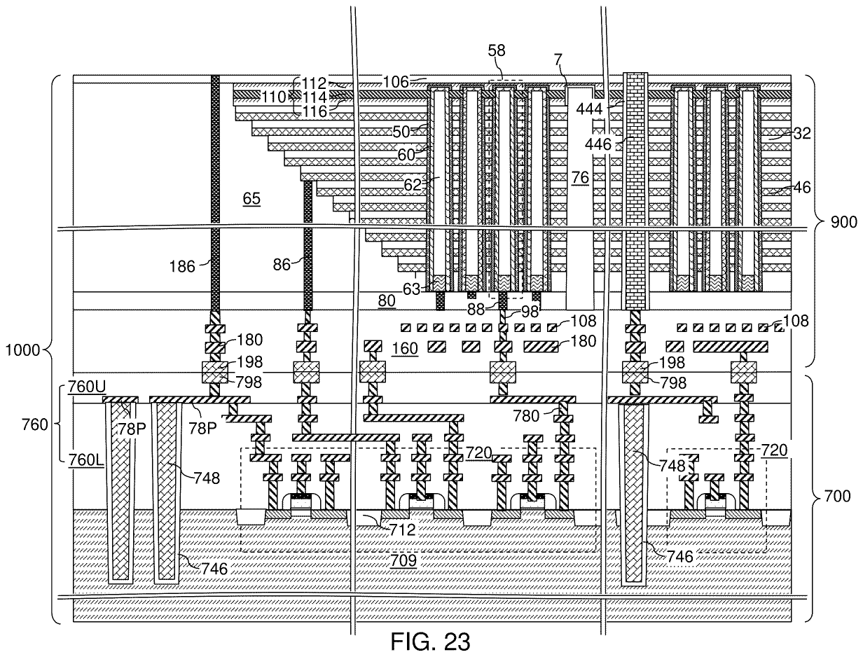

Referring to FIG. 22, a unit bonded assembly 1000 can be formed by bonding the memory-controller die 700 described with reference to FIG. 21 with the memory die 900 described with reference to FIG. 17. A plurality of unit bonded assemblies 1000 can be formed. Each of the plurality of unit bonded assemblies 1000 constitutes a bonded assembly 1000. The memory-controller die 700 can be attached to the memory die 900 by bonding the controller-die front bonding structures 798 to the memory-die front bonding structures 198. The bonding between mating pairs of a respective memory die 900 and a respective memory-controller die 700 may be performed employing a wafer-to-wafer bonding process in which a two-dimensional array of memory dies 900 is bonded to a two-dimensional array of memory-controller dies 700, by a die-to-wafer bonding process (in which a diced die is bonded to a wafer), or by a die-to-die bonding process (in which two diced dies are bonded to each other). The controller-die front bonding structures 798 within each memory-controller die 700 can be bonded to the memory-die front bonding structures 198 within a respective memory die 900 by metal-to-metal bonding, such as copper-to-copper bonding. The memory die 900 comprises alternating stacks (32, 46) of insulating layers 32 and electrically conductive layers 46 and memory-die front dielectric material layers 160 embedding memory-die front metal interconnect structures (180, 108, 98) and memory-die front bonding structures 198. Memory stack structures 55 vertically extend through a respective one of the alternating stacks (32, 46) in a memory array region 100, and layer contact via structures 86 contact a respective electrically conductive layer 46 within the alternating stacks (32, 46) in a contact region 200. In one embodiment, through-stack via structures 446 vertically extend through vertically-extending openings 449 in the alternating stacks (32, 46) within a center region of the memory die 900, which is defined as a volume within the memory die 900 that is more proximal to a geometrical center GC of the memory die 900 than to a periphery of the memory die 900 defined by outer sidewalls of the memory die 900 in a plan view along a vertical direction. A memory-controller die 700 comprises a memory controller circuit 720 including a control circuitry for controlling operation of the electrically conductive layers 46 and further comprises controller-die front dielectric material layers 760 embedding controller-die front metal interconnect structures 780 and controller-die front bonding structures 798. The controller-die front bonding structures 798 are bonded to the memory-die front bonding structures 198.

Within each bonded assembly 1000 (i.e., a unit bonded assembly 1000) of a respective memory die 900 and a respective memory-controller die 700, the respective memory die 900 comprises respective memory-die front bonding structures 198 embedded within respective memory-die front dielectric material layers 160, and the respective memory-controller die 700 comprises respective controller-die front bonding structures 798 embedded within respective controller-die front dielectric material layers 760 and bonded to the respective memory-die front bonding structures 198. In one embodiment, the respective controller-die front bonding structures 798 are bonded to the respective memory-die front bonding structures 198 via metal-to-metal bonding, such as copper-to-copper bonding.

In one embodiment, dielectric-to-dielectric bonding, such as silicon oxide-to-silicon oxide bonding may be employed in conjunction with the metal-to-metal bonding. In this case, a topmost memory-die front dielectric material layer of the respective memory-die front dielectric material layers 160 is bonded to a topmost controller-die front dielectric material layer among the controller-die front dielectric material layers 760 via dielectric-to-dielectric bonding (i.e., hybrid bonding is used to bond the respective memory die to the respective memory-controller die).

In one embodiment, the respective memory die 900 includes a respective three-dimensional array of memory elements (e.g., flash memory cells comprising portions of a memory material layer 54), and the respective memory-controller die 700 includes a respective memory controller circuit 720 configured to control operation of the respective three-dimensional array of memory elements. In one embodiment, a subset of the through-stack via structures 446 is electrically connected to a subset of semiconductor devices (e.g., input/output control devices, such as field effect transistors) in the respective memory controller circuit 720 of the memory-controller die 700 through a subset of the memory-die front metal interconnect structures (180, 108, 98) and through a subset of the controller-die front metal interconnect structures 780.

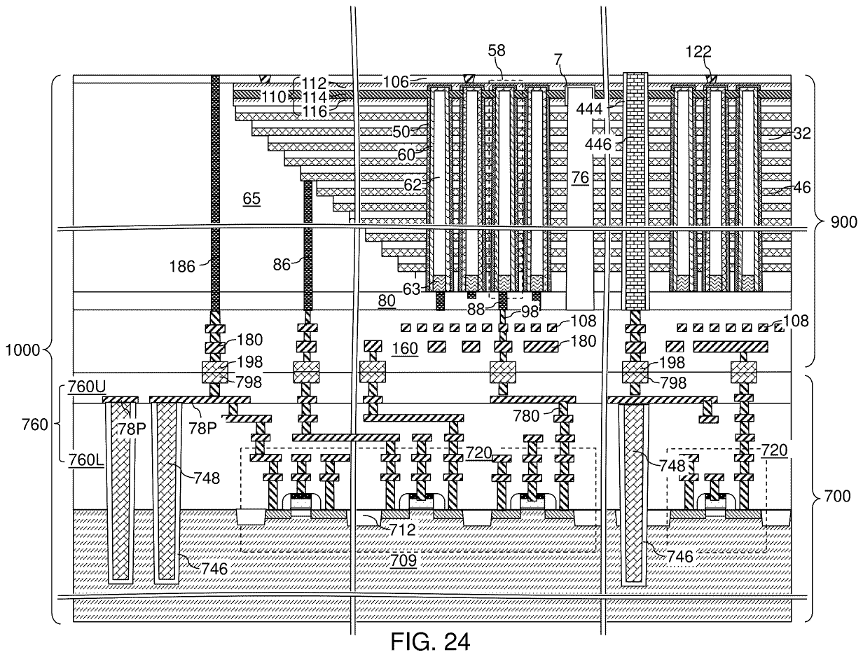

Referring to FIG. 23, the carrier substrate 9 may be removed, for example, by grinding, polishing, cleaving, an isotropic etch process, and/or an anisotropic etch process. If a polishing process such as a chemical mechanical polishing process is employed to remove the carrier substrate 9, the first memory-die proximal dielectric material layer 106 may be subsequently employed as a polishing stopper material layer. If an etch process such as a wet etch process is employed to remove the carrier substrate 9, the first memory-die proximal dielectric material layer 106 may be subsequently employed as an etch stop material layer. End surfaces of the through-stack via structures 446 may be physically exposed upon removal of the carrier substrate 9.

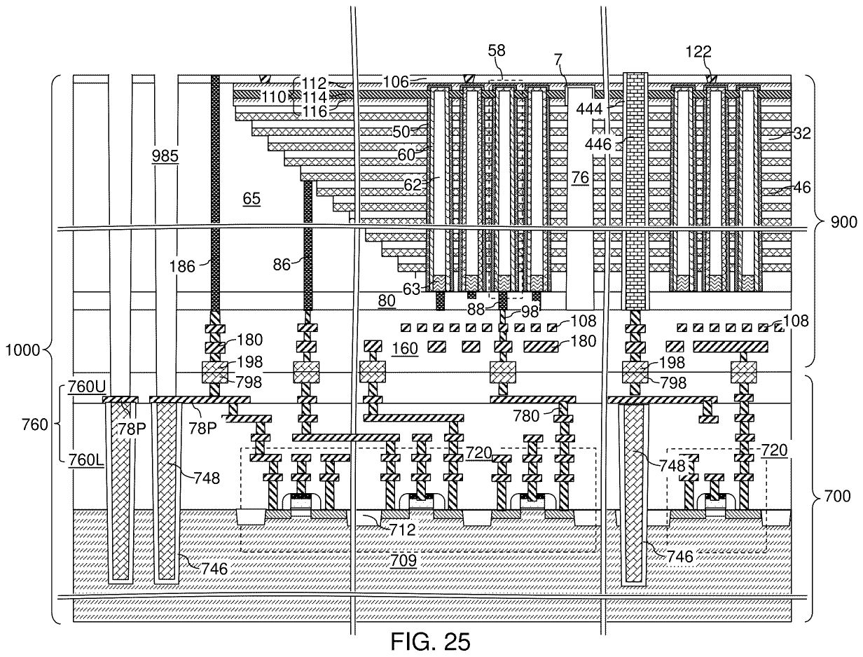

Referring to FIG. 24, backside via openings can be formed through the first memory-die proximal dielectric material layer 106 on the backside surface (i.e., a distal surface) of the source layer 110 by performing a combination of a lithographic patterning process and an anisotropic etch process. At least one electrically conductive material can be deposited in the backside via openings, and over the distal surface of the first memory-die proximal dielectric material layer 106. The at least one electrically conductive material may comprise a combination of a metallic barrier material (such as TiN, TaN, WN, and/or MoN) and an aluminum-based material comprising aluminum at an atomic percentage greater than 90%. Alternatively, a refractory metal layer (e.g., tungsten) may be used instead of the aluminum-based material. A planarization process can be performed to remove portions of the at least one electrically conductive material from above the horizontal plane including the top surface of the first memory-die proximal dielectric material layer 106 to form least one source connection structure 122 in the backside via openings.

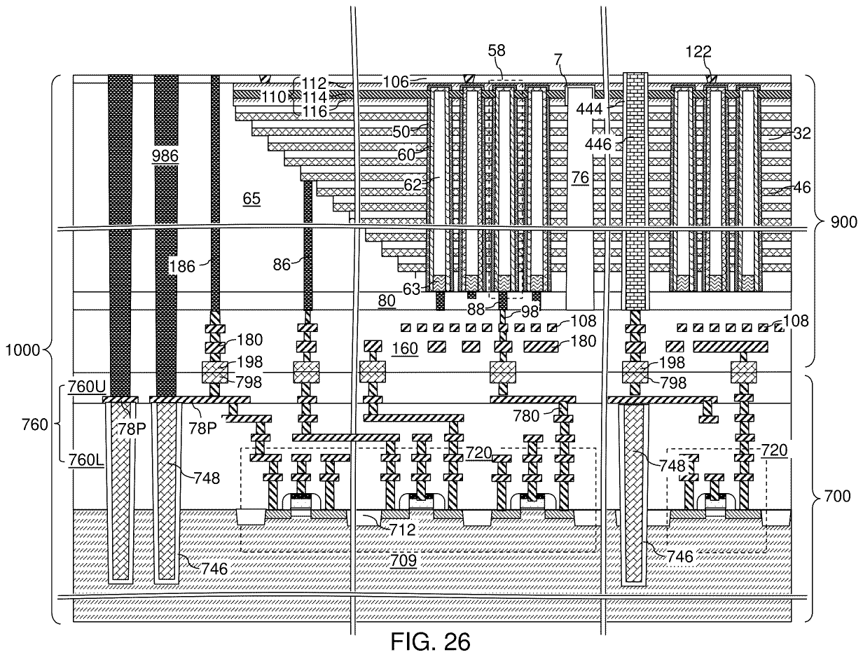

Referring to FIG. 25, an etch mask layer, such as a patterned photoresist layer, can be formed over the first memory-die proximal dielectric material layer 106. The etch mask layer comprises openings within areas of the through-substrate via structures 748. An anisotropic etch process can be performed to transfer the pattern of the openings in the etch mask layer though the entire height of the memory die 900 and through the upper controller-die front dielectric material layers 760U. The conductive pads 78P can be used as etch stop structures. An inter-die connection via cavity 985 can be formed in each volume from which materials of the memory die 900 and the upper controller-die front dielectric material layers 760P are removed. In one embodiment, a top surface of the respective conductive pad 78P may be physically exposed at the bottom of each inter-die connection via cavity 985.

Each inter-die connection via cavity 985 comprises a straight or substantially-straight sidewall having a top periphery within a horizontal plane including a distal horizontal surface of the memory-die proximal dielectric material layer 106, and having a bottom periphery located within a horizontal plane including top surfaces of the conductive pads 78P of the controller-die front metal interconnect structures 780. The top periphery of each inter-die connection via cavity 985 may have a greater lateral dimension than the bottom periphery of the same inter-die connection via cavity 985. In an illustrative example, the lateral dimension (such as a diameter) of the top periphery of a inter-die connection via cavity 985 may be in a range from 5 microns to 60 microns, such as from 10 microns to 40 microns, although lesser or greater lateral dimensions may also be employed. The vertical extent of each inter-die connection via cavity 985 may be in a range from 5 microns to 100 microns, such as from 10 microns to 60 microns, although lesser or greater vertical extents may also be employed. The etch mask layer may be subsequently removed, for example, by ashing.

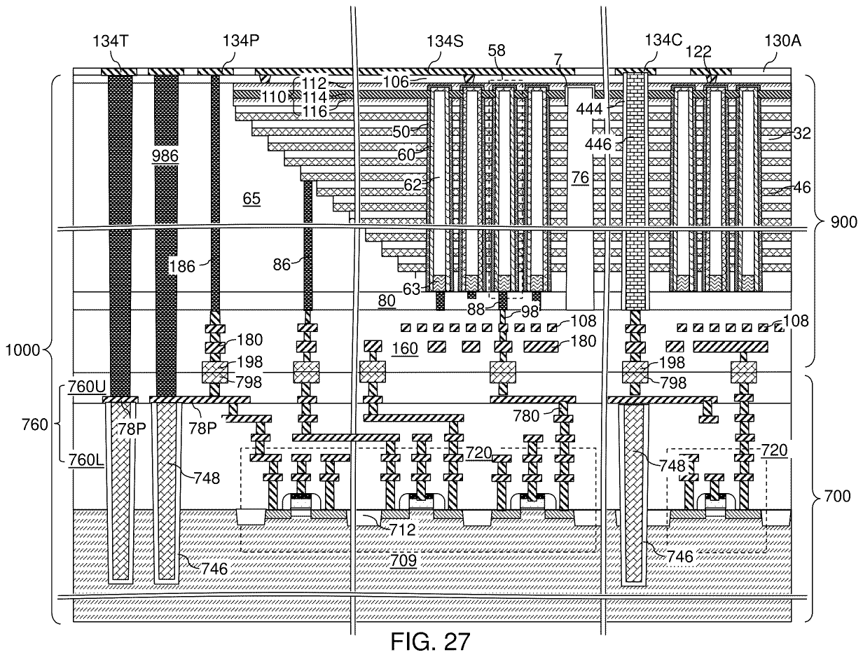

Referring to FIG. 26, at least one electrically conductive material, such as a combination of a conductive metallic nitride material (e.g., TiN, TaN, WN or MoN) and a metal fill material (such as W, Cu, Co, Ru, Mo, etc.) may be deposited in remaining volumes of the inter-die connection via cavities 985 and over the memory-die proximal dielectric material layer 106. A planarization process, such as a chemical mechanical polishing process and/or a recess etch process, can be performed to remove a horizontally-extending portion of the at least one electrically conductive material. Each remaining portion of the at least one electrically conductive material constitutes a respective inter-die connection via structure 986. In one embodiment, top surfaces of the inter-die connection via structures 986 may be formed within a horizontal plane including a distal surface of the memory-die proximal dielectric material layer 106.

Generally, inter-die connection via structures 986 can be formed through the first memory-die dielectric material portion (such as a retro-stepped dielectric material portion 65) and a first subset of the controller-die front dielectric material layers 760 and directly on a respective one of the controller-die front metal interconnect structures 780 (e.g., on one of the conductive pads 78P). In one embodiment, an electrically conductive path from an inter-die connection via structure 986 to a respective through-substrate via structure 748 is formed upon formation of each inter-die connection via structure 986.

In one embodiment, the memory die 900 comprises a memory-die proximal dielectric material layer 106 that is vertically spaced from the memory controller die 700 by the alternating stack (32, 46). A first end surface of each inter-die connection via structure 986 may contact a conductive pad 78P, and a second end surface of each inter-die connection via structure 986 may be coplanar with a horizontal surface of the memory-die proximal dielectric material layer 106. In one embodiment, the second end surface of each inter-die connection via structure 986 may have a greater lateral extent than the first end surface of a respective inter-die connection via structure 986.

In one embodiment, the memory-die proximal dielectric material layer 106 is in direct contact with the source layer 110 that is interposed between first alternating stack (32, 46) and the memory-die proximal dielectric material layer 106. In one embodiment, each inter-die connection via structure 986 vertically extends through a memory-die dielectric material portion (such as a retro-stepped dielectric material portion 65), and has a greater vertical extent than the alternating stack (32, 46). In one embodiment, each inter-die connection via structure 986 has a greater vertical extent than the memory-die dielectric material portion 65.

Referring to FIG. 27, memory-die backside dielectric material layers 130A embedding memory-die backside metal interconnect structures (134S, 134P, 134C, 134T) can be formed upon the inter-die connection via structure 986. The memory-die backside metal interconnect structures (134S, 134P, 134C, 134T) may comprise source-connection backside metal interconnect structures 134S that are electrically connected to the source layer 110, peripheral backside metal interconnect structures 134P that are electrically connected to the peripheral connection via structures 186, central backside metal interconnect structures 134C that are electrically connected to the through-stack via structures 446, and through-connection backside metal interconnect structures 134T that are electrically connected to the inter-die connection via structures 986.

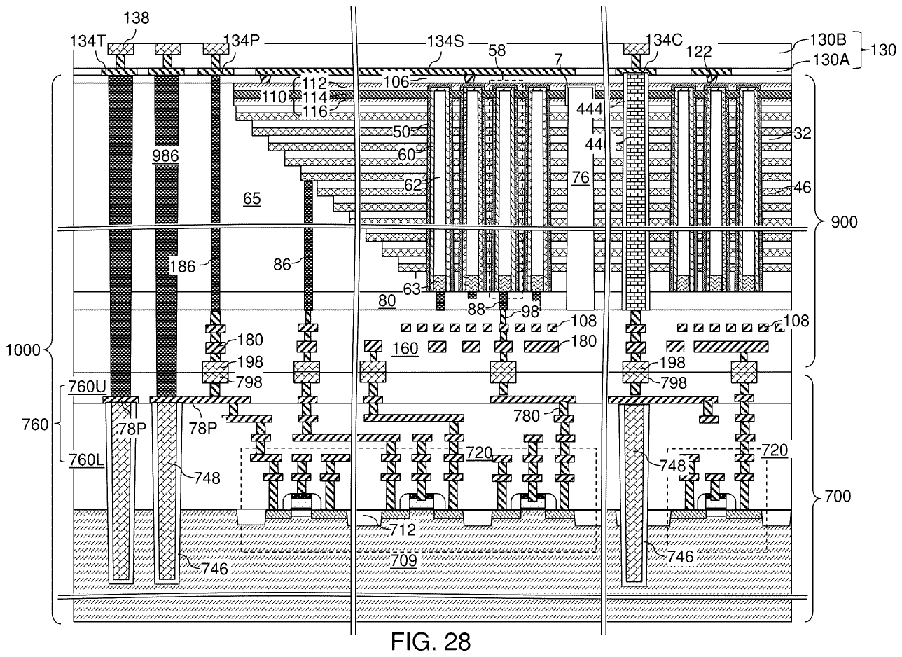

Referring to FIG. 28, an additional memory-die backside dielectric material layer 130B over layer 130A to form a combined memory-die backside dielectric material layer 130. The additional memory-die backside dielectric material layer 130B embeds memory-die backside bonding structures 138 located over the memory-die backside metal interconnect structures (134S, 134P, 134C, 134T). Each of the memory-die backside bonding structures 138 may be electrically connected to a respective one of the memory-die backside metal interconnect structures (134S, 134P, 134C, 134T). In one embodiment, physically exposed surfaces of the memory-die backside bonding structures 138 may be coplanar with the horizontally-exposed surface of the combined memory-die backside dielectric material layer 130.

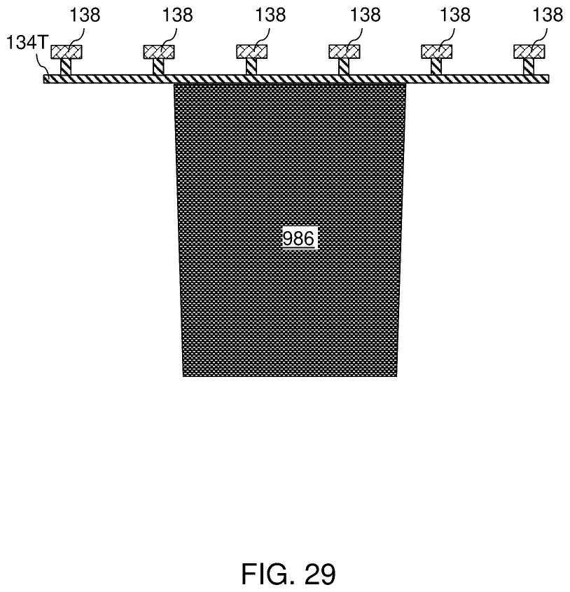

Referring to FIG. 29, a region of an alternative configuration of the first exemplary bonded assembly according to an embodiment of the present disclosure is illustrated. In the alternative configuration, a plurality of memory-die backside bonding structures 138 can be electrically connected to a single inter-die connection via structure 986 through a set of through-connection backside metal interconnect structures 134T. In an illustrative example, each of the memory-die backside bonding structures 138 may have a lateral dimension in a range from 1 micron to 5 microns. The through-connection backside metal interconnect structures 134T may have a lateral dimension in a range from 5 microns to 60 microns, such as from 10 microns to 40 microns.

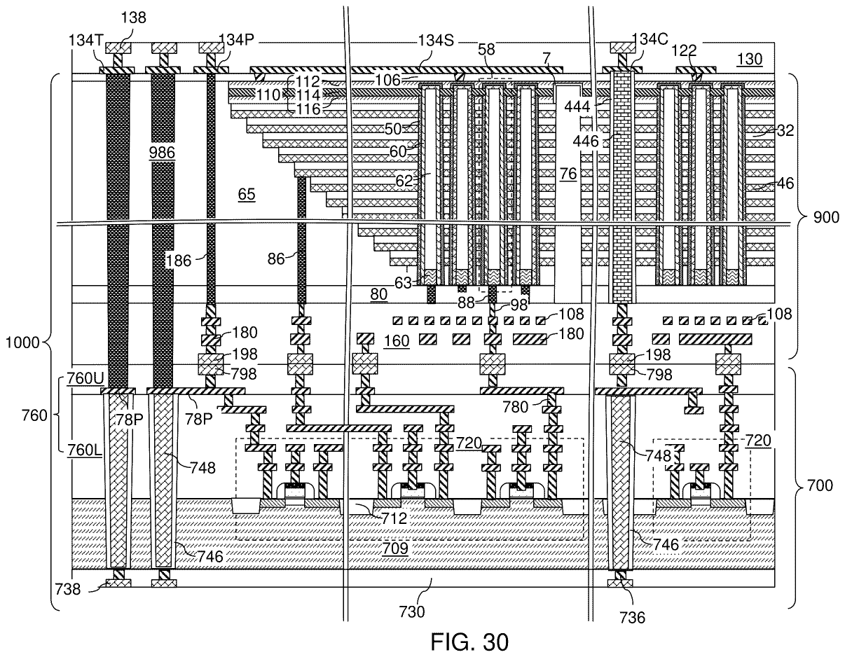

Referring to FIG. 30, the controller-die substrate 709 can be thinned from the backside, for example, by cleaving, grinding, polishing, at least one isotropic etch process, and/or at least one anisotropic etch process. End surfaces of the through-substrate via structures 748 may be employed as stopper surfaces during the removal of the backside portion of the controller-die substrate 709. In one embodiment, a chemical mechanical polishing process may be employed as a terminal processing step during the thinning of the controller-die substrate 709. In one embodiment, physically exposed end surfaces of the through-substrate via structures 748 and the dielectric isolation liners 746 may be coplanar with the backside surface of the controller-die substrate 709.

Controller-die backside metal interconnect structures 736 and controller-die backside bonding structures 738 embedded within controller-die backside dielectric material layers 730 may be formed. In one embodiment, physically exposed planar end surfaces of the controller-die backside bonding structures 738 may be coplanar with the physically exposed horizontal surface of the controller-die backside dielectric material layers 730. The controller-die backside bonding structures 738 are electrically connected to a respective one of the through-substrate via structures 748. In one embodiment, the pattern of the controller-die backside bonding structures 738 may be a mirror image pattern of the memory-die backside bonding structures 138.

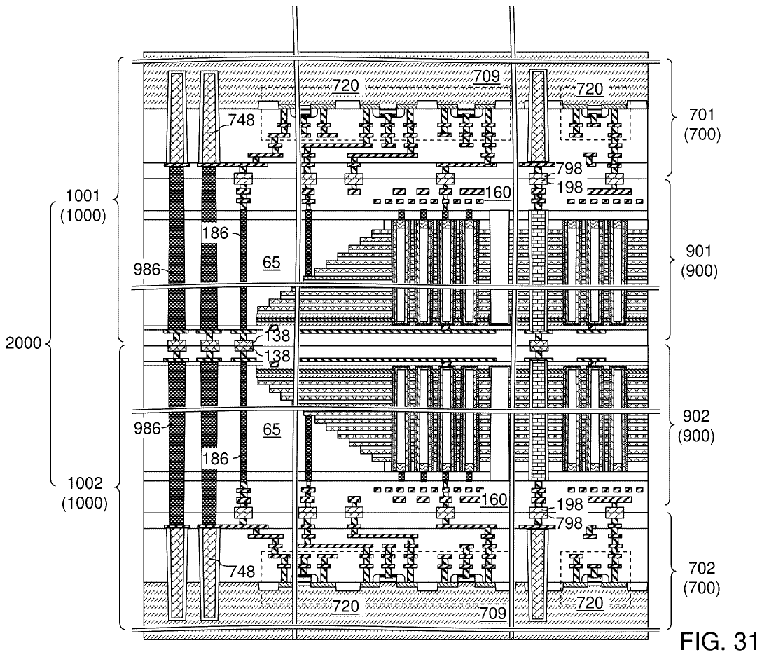

Referring to FIG. 31, a second exemplary bonded assembly 2000 according to an embodiment of the present disclosure is illustrated. The second exemplary bonded assembly 2000 is a composite bonded assembly that can be formed by bonding two instances of the first exemplary bonded assembly 1000 illustrated in FIG. 28. In this case, the first instance of the first exemplary bonded assembly 1000 is herein referred to as a first bonded assembly 1001, and the second instance of the first exemplary bonded assembly 1000 is herein referred to as a second bonded assembly 1002. The memory die 900 within the first bonded assembly 1001 is herein referred to as a first memory die 901, and the memory controller die 700 within the first bonded assembly 1001 is herein referred to as a first memory controller die 701. The memory die 900 within the second bonded assembly 1002 is herein referred to as a second memory die 902, and the memory controller die 700 within the second bonded assembly 1002 is herein referred to as a second memory controller die 702. In one embodiment, the second exemplary bonded assembly may be formed by bonding the first memory-die backside bonding structures 138 of the first bonded assembly 1001 to the second memory-die backside bonding structures 138 of the second bonded assembly 1002.

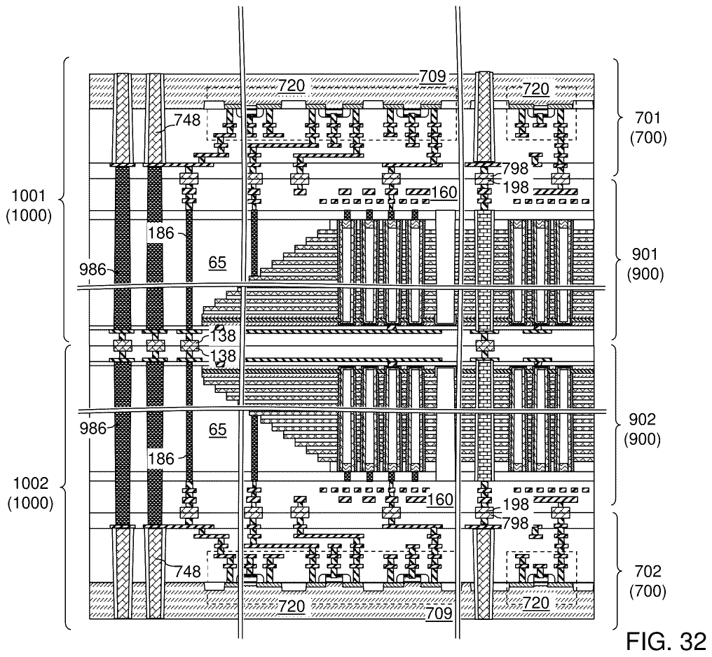

Referring to FIG. 32, the controller-die substrates 709 of the first memory controller die 701 and the second memory controller die 702 may be thinned from their respective backside. The processing steps described with reference to FIG. 30 may be employed with suitable modifications to the process parameters as needed.

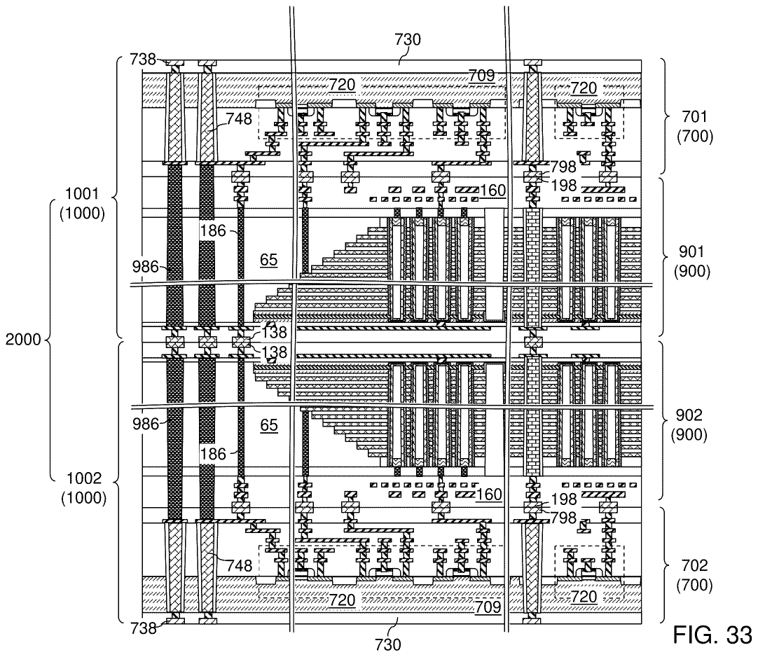

Referring to FIG. 33, controller-die backside metal interconnect structures 736 and controller-die backside bonding structures 738 embedded within controller-die backside dielectric material layers 730 may be formed on each of the first memory die 701 and the second memory die 702. The processing steps described with reference to FIG. 30 may be employed with suitable modifications to the process parameters as needed.

An electrically conductive path through the bonded assembly 2000 which includes the inter-die connection via structures 986 and through-substrate via structures 748 can significantly reduce electrical resistance and process cost compared to an electrically conductive path that includes plural stacked conductive layers that are located only in a respective die of the bonded assembly 2000. Specifically, the diameter of the inter-die connection via structures 986 may be relatively large to reduce their electrical resistance, and the processing cost may be decreased due to the relative ease of etching the large diameter inter-die connection via cavities 985 through dielectric layers (65, 160), which in one embodiment may comprise the same dielectric material, such as silicon oxide.

Referring to all drawings of the present disclosure and according to various embodiments of the present disclosure, a semiconductor structure (e.g., bonded assembly 2000) comprises: a first memory die 901 comprising a first alternating stack 32 of first insulating layers and first electrically conductive layers, first memory opening fill structures 58 vertically extending through the first alternating stack 32 and comprising a respective vertical stack of first memory elements (e.g., portions of the memory film 50), a first memory-die dielectric material portion 65 laterally offset from the first alternating stack 32, and first memory-die front dielectric material layers 160 embedding first memory-die front metal interconnect structures 180 and first memory-die front bonding structures 198; a first memory controller die 701 comprising a first controller-die substrate 709, a first memory controller circuit 720 configured to control operation of the first memory die 901 and located on the first controller-die substrate 709, and first controller-die front dielectric material layers 760 embedding first controller-die front metal interconnect structures 780 and first controller-die front bonding structures 798 that are bonded to the first memory-die front bonding structures 198; and a first inter-die connection via structure 986 vertically extending through the first memory-die dielectric material portion 65 and a first subset of the first controller-die front dielectric material layers 760 and having a first end surface contacting one of the first controller-die front metal interconnect structures 780.

In one embodiment, the semiconductor structure comprises a first through-substrate via structure 748 vertically extending through the first controller-die substrate 709 and electrically connected to the first inter-die connection via structure 986. In one embodiment, a first end surface of the first through-substrate via structure 748 is in contact with said one of the first controller-die front metal interconnect structures 780. In one embodiment, a second end surface of the first through-substrate via structure 748 is coplanar with a backside surface of the first controller-die substrate 709. In one embodiment, the first end surface of the first through-substrate via structure 748 has a greater lateral extent than the second end surface of the first through-substrate via structure 748.

In one embodiment, the first memory controller die 701 comprises first controller-die backside dielectric material layers embedding first controller-die backside metal interconnect structures and first controller-die backside bonding structures 738, wherein the first through-substrate via structure 748 is electrically connected to one of the first controller-die backside bonding pads 738. In one embodiment, the first memory controller die 701 comprises a first dielectric isolation liner 746 laterally surrounding the first through-substrate via structure 748 and laterally surrounded by the first controller-die substrate 709 and a second subset of the first controller-die front dielectric material layers 760.

In one embodiment, the first memory die 901 comprises a first memory-die proximal dielectric material layer 106 that is vertically spaced from the first memory controller die 701 by the first alternating stack 32, wherein a second end surface of the first inter-die connection via structure 986 is coplanar with a horizontal surface of the first memory-die proximal dielectric material layer 106. In one embodiment, the second end surface of the first inter-die connection via structure 986 has a greater lateral extent than the first end surface of the first inter-die connection via structure 986. In one embodiment, the first memory-die proximal dielectric material layer 106 is in direct contact with a first source layer 110 that is interposed between the first alternating stack 32 and the first memory-die proximal dielectric material layer 106.

In one embodiment, the one of the first controller-die front metal interconnect structures 780 comprises a first conductive pad 78P having a same thickness and a same material composition as first metal line structures embedded within the first controller-die front dielectric material layers 760 and contacting a respective first metal via structure.

In one embodiment, the first controller-die front bonding structures 798 are bonded to the first memory-die front bonding structures 198 by metal-to-metal bonding. In one embodiment, the first memory-die dielectric material portion 65 has a greater vertical extent than the first alternating stack 32; and the first inter-die connection via structure 986 has a greater vertical extent than the first memory-die dielectric material portion 65.

In one embodiment, the semiconductor structure comprises a second memory die 902 that is bonded to the first memory die 901, wherein the second memory die 902 comprises a second alternating stack of second insulating layers and second electrically conductive layers, second memory opening fill structures 58 vertically extending through the second alternating stack and comprising a respective vertical stack of second memory elements, a second memory-die dielectric material portion 65 laterally offset from the second alternating stack, and second memory-die front dielectric material layers 160 embedding second memory-die front metal interconnect structures 180 and second memory-die front bonding structures 198.

In one embodiment, first memory die 901 comprises first memory-die backside dielectric material layers 130 embedding first memory-die backside metal interconnect structures 134 and first memory-die backside bonding structures 138; and the first inter-die connection via structure 986 is electrically connected to one of the first memory-die backside bonding structures 138. In one embodiment, the second memory die 902 comprises second memory-die backside dielectric material layers embedding second memory-die backside metal interconnect structures and second memory-die backside bonding structures 138; and the first memory-die backside bonding structures 138 are bonded to the second memory-die backside bonding structures 138 by metal-to-metal bonding.

In one embodiment, the semiconductor structure comprises: a second memory controller die 702 comprising a second controller-die substrate 709, a second memory controller circuit 720 configured to control operation of the second memory die 902 and located on the second controller-die substrate 709, and second controller-die front dielectric material layers 760 embedding second controller-die front metal interconnect structures 780 and second controller-die front bonding structures 798 that are bonded to the second memory-die front bonding structures 198; and a second inter-die connection via structure 986 vertically extending through the second memory-die dielectric material portion 65 and a first subset of the second controller-die front dielectric material layers 760 and having a first end surface contacting one of the second controller-die front metal interconnect structures 780.

In one embodiment, the semiconductor structure further comprises a plurality of stacked bonded assemblies 1000. Each bonded assembly 1000 of the plurality of bonded assemblies 1000 contains a respective unit bonded assembly 1000 of a respective memory die 900 including a respective three-dimensional array of memory elements (comprising portions of a memory material layer 54) and an array of vertical semiconductor channels 60, and a respective memory-controller die 700 including a respective memory controller circuit 720 configured to control operation of the respective memory die 900. Each vertically neighboring pair of bonded assemblies 1000 of the plurality of bonded assemblies 1000 is bonded to each other through a respective pair of arrays of bonding structures (138) such that electrically conductive paths (748, 986) vertically extend from a first horizontal plane including a bottom surface of a bottommost bonded assembly 1000 of the plurality of bonded assemblies 1000 at least to a second horizontal plane including a top surface of a topmost bonded assembly 1000 of the plurality of bonded assemblies 1000.

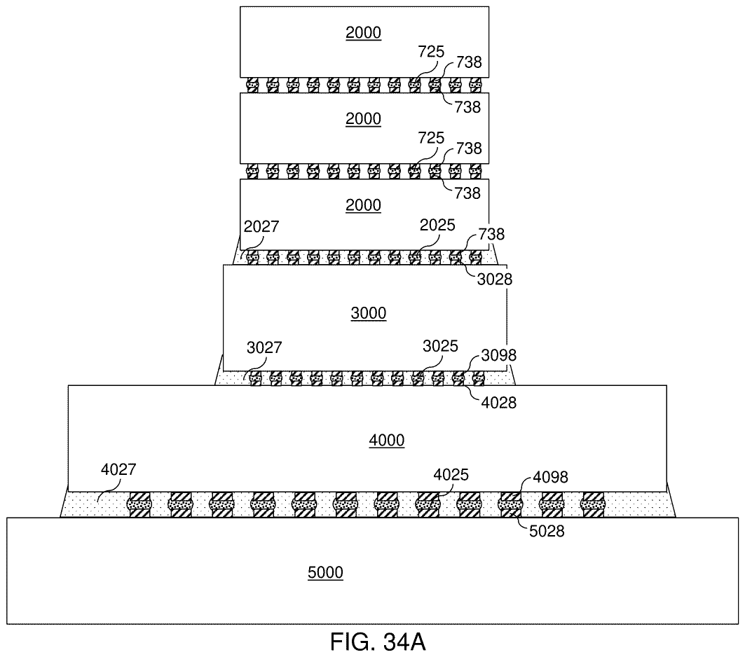

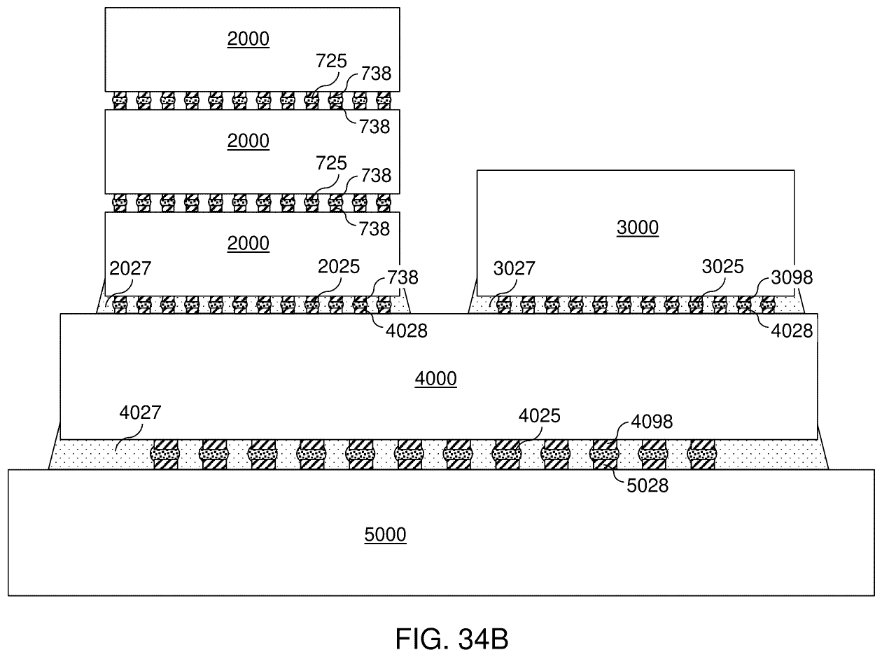

According to an aspect of the present disclosure, a plurality of high bandwidth flash memory assemblies 2000 can be bonded to additional semiconductor dies to provide a semiconductor package structure (3000, 4000, 5000) comprising package-side bump structures (3028, 4028). FIG. 34A and FIG. 34B illustrate exemplary configurations for semiconductor structures including a respective semiconductor package structure (3000, 4000, 5000). FIG. 34A is a vertical cross-sectional view of a first exemplary structure including multiple instances of the second exemplary bonded assembly according to an embodiment of the present disclosure. FIG. 34B is a vertical cross-sectional view of a second exemplary structure including multiple instances of the second exemplary bonded assembly according to an embodiment of the present disclosure.

The first exemplary structure illustrated in FIG. 34A includes a vertical stack of multiple high bandwidth flash memory assemblies 2000 that are stacked along a vertical direction, an optional system-level logic die 3000, an optional interposer 4000, and a packaging substrate 5000 according to an embodiment of the present disclosure. The multiple instances of a high bandwidth flash memory assembly 2000 are vertically stacked, and are bonded to each other using arrays of inter-memory solder material portions 725. Each inter-memory solder material portions 725 may be bonded to a respective pair of controller-die backside bonding structures 738. The vertical stack of multiple high bandwidth flash memory assemblies 2000 may be bonded to the system-level logic die 3000.

The second exemplary structure illustrated in FIG. 34B includes multiple instances of a high bandwidth flash memory assembly 2000 that are stacked along a vertical direction, the optional system-level logic die 3000, the optional interposer 4000, and the packaging substrate 5000 according to an embodiment of the present disclosure. The vertical stack of multiple high bandwidth flash memory assemblies 2000 may be bonded to the interposer 4000.

The system-level logic die 3000, if present, controls the operation of the memory-controller dies 700 in each bonded assembly 1000 of the high bandwidth flash memory assembly 2000. The system-level logic die 3000 may comprise at least one of a central processing unit (CPU), a graphics processing unit (GPU), neural processing unit (NPU), and a digital signal processor (DSP). A bottommost instance of the high bandwidth flash memory assembly 2000 may be bonded to the system-level logic die 3000 or to the interposer 4000 through an array of solder material portions 2025. In one embodiment, the controller-die backside bonding structures 738 of the bottommost instance of the high bandwidth flash memory assembly 2000 may be bonded to top logic-die bump structures 3028 through an array of solder material portions 2025 as illustrated in FIG. 34A. Alternatively, the controller-die backside bonding structures 738 of the bottommost instance of the high bandwidth flash memory assembly 2000 may be bonded to top interposer bump structures 4028 through an array of solder material portions 2025 as illustrated in FIG. 34B. An underfill material portion 2027 may be applied around the array of solder material portions 2025.

The interposer 4000 may comprise any type of interposer known in the art. For example, the packaging substrate 5000 may comprise a ceramic interposer or an organic interposer. The system-level logic die 3000 may be bonded to the interposer 4000 through an array of solder material portions 3025. For example, the bottom logic-die bump structures 3098 of the system-level logic die 3000 may be bonded to top interposer bump structures 4028 of the interposer 4000 through the array of solder material portions 3025. An underfill material portion 3027 may be applied around the array of solder material portions 3025.

The packaging substrate 5000 may comprise any type of packaging substrate known in the art. For example, the packaging substrate 5000 may comprise a cored packaging substrate, a non-cored packaging substrate, etc. The interposer 4000 may be bonded to the packaging substrate 5000 through an array of solder material portions 4025. For example, the bottom interposer bump structures 4098 of the interposer 4000 may be bonded to top substrate bump structures 5028 of the packaging substrate 5000 through the array of solder material portions 4025. An underfill material portion 4027 may be applied around the array of solder material portions 4025.

For each bonded assembly which may comprise a high bandwidth flash memory assembly 2000, a semiconductor package structure (2000, 3000, 4000, 5000) comprising package-side bump structures (3028, 4028) may be provided. The first memory-controller die 700 of the high bandwidth flash memory assembly 2000 comprises first controller-die backside bonding structures 738 located on an opposite side of the first controller-die copper bonding pads (which may comprise controller-die front bonding structures 798). The package-side bump structures (3028, 4028) are bonded to the first controller-die backside bonding structures 738 through an array of solder material portions 2025. In one embodiment, the semiconductor package structure (2000, 3000, 4000, 5000) comprises: an additional bonded assembly (e.g., an additional high bandwidth flash memory assembly 2000) that comprises a third memory die 900 and a fourth memory die 900 that are bonded to each other through hybrid bonding; or a processor die (e.g., the system-level logic die 3000) that comprises at least one of a central processing unit (CPU), a graphics processing unit (GPU), neural processing unit (NPU), and a digital signal processor (DSP).

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A semiconductor structure, comprising:
a first memory die comprising a first alternating stack of first insulating layers and first electrically conductive layers, first memory opening fill structures vertically extending through the first alternating stack and comprising a respective vertical stack of first memory elements, a first memory-die dielectric material portion laterally offset from the first alternating stack, and first memory-die front dielectric material layers embedding first memory-die front metal interconnect structures and first memory-die front bonding structures;
a first memory controller die comprising a first controller-die substrate, a first memory controller circuit configured to control operation of the first memory die and located on the first controller-die substrate, and first controller-die front dielectric material layers embedding first controller-die front metal interconnect structures and first controller-die front bonding structures that are bonded to the first memory-die front bonding structures; and
a first inter-die connection via structure vertically extending through the first memory-die dielectric material portion and a first subset of the first controller-die front dielectric material layers and having a first end surface contacting one of the first controller-die front metal interconnect structures.

2. The semiconductor structure of claim 1, further comprising a first through-substrate via structure vertically extending through the first controller-die substrate and electrically connected to the first inter-die connection via structure.

3. The semiconductor structure of claim 2, wherein a first end surface of the first through-substrate via structure is in contact with said one of the first controller-die front metal interconnect structures.

4. The semiconductor structure of claim 3, wherein a second end surface of the first through-substrate via structure is coplanar with a backside surface of the first controller-die substrate.

5. The semiconductor structure of claim 4, wherein the first end surface of the first through-substrate via structure has a greater lateral extent than the second end surface of the first through-substrate via structure.

6. The semiconductor structure of claim 2, wherein the first memory controller die comprises first controller-die backside dielectric material layers embedding first controller-die backside metal interconnect structures and first controller-die backside bonding structures, and wherein the first through-substrate via structure is electrically connected to one of the first controller-die backside bonding pads.

7. The semiconductor structure of claim 2, wherein the first memory controller die comprises a first dielectric isolation liner laterally surrounding the first through-substrate via structure, and laterally surrounded by the first controller-die substrate and a second subset of the first controller-die front dielectric material layers.

8. The semiconductor structure of claim 2, wherein the first memory die comprises a first memory-die proximal dielectric material layer that is vertically spaced from the first memory controller die by the first alternating stack, wherein a second end surface of the first inter-die connection via structure is coplanar with a horizontal surface of the first memory-die proximal dielectric material layer.

9. The semiconductor structure of claim 8, wherein the second end surface of the first inter-die connection via structure has a greater lateral extent than the first end surface of the first inter-die connection via structure.

10. The semiconductor structure of claim 8, wherein the first memory-die proximal dielectric material layer is in direct contact with a first source layer that is interposed between the first alternating stack and the first memory-die proximal dielectric material layer.

11. The semiconductor structure of claim 1, wherein said one of the first controller-die front metal interconnect structures comprises a first conductive pad having a same thickness and a same material composition as first metal line structures embedded within the first controller-die front dielectric material layers and contacting a respective first metal via structure.

12. The semiconductor structure of claim 1, wherein:
the first controller-die front bonding structures are bonded to the first memory-die front bonding structures by metal-to-metal bonding; and
each of the first memory opening fill structures further comprises a vertical semiconductor channel.

13. The semiconductor structure of claim 1, wherein:
the first memory-die dielectric material portion has a greater vertical extent than the first alternating stack; and
the first inter-die connection via structure has a greater vertical extent than the first memory-die dielectric material portion.

14. The semiconductor structure of claim 1, further comprising a second memory die that is bonded to the first memory die, wherein the second memory die comprises a second alternating stack of second insulating layers and second electrically conductive layers, second memory opening fill structures vertically extending through the second alternating stack and comprising a respective vertical stack of second memory elements, a second memory-die dielectric material portion laterally offset from the second alternating stack, and second memory-die front dielectric material layers embedding second memory-die front metal interconnect structures and second memory-die front bonding structures.

15. The semiconductor structure of claim 14, wherein:
the first memory die comprises first memory-die backside dielectric material layers embedding first memory-die backside metal interconnect structures and first memory-die backside bonding structures;
the first inter-die connection via structure is electrically connected to one of the first memory-die backside bonding structures;
the second memory die comprises second memory-die backside dielectric material layers embedding second memory-die backside metal interconnect structures and second memory-die backside bonding structures; and
the first memory-die backside bonding structures are bonded to the second memory-die backside bonding structures by metal-to-metal bonding.

16. The semiconductor structure of claim 14, further comprising:
a second memory controller die comprising a second controller-die substrate, a second memory controller circuit configured to control operation of the second memory die and located on the second controller-die substrate, and second controller-die front dielectric material layers embedding second controller-die front metal interconnect structures and second controller-die front bonding structures that are bonded to the second memory-die front bonding structures; and
a second inter-die connection via structure vertically extending through the second memory-die dielectric material portion and a first subset of the second controller-die front dielectric material layers and having a first end surface contacting one of the second controller-die front metal interconnect structures.

17. The semiconductor structure of claim 1, further comprising a plurality of stacked bonded assemblies, wherein:
each bonded assembly of the plurality of bonded assemblies contains a respective unit bonded assembly of a respective memory die including a respective three-dimensional array of memory elements and an array of vertical semiconductor channels, and a respective memory-controller die including a respective memory controller circuit configured to control operation of the respective memory die; and
each vertically neighboring pair of bonded assemblies of the plurality of bonded assemblies is bonded to each other through a respective pair of arrays of bonding structures such that electrically conductive paths vertically extend from a first horizontal plane including a bottom surface of a bottommost bonded assembly of the plurality of bonded assemblies at least to a second horizontal plane including a top surface of a topmost bonded assembly of the plurality of bonded assemblies.

18. A method of forming a semiconductor structure, comprising:
providing a first memory die comprising a first carrier substrate, a first alternating stack of first insulating layers and first electrically conductive layers, first memory opening fill structures vertically extending through the first alternating stack and comprising a respective vertical stack of first memory elements, a first memory-die dielectric material portion laterally offset from the first alternating stack, and first memory-die front dielectric material layers embedding first memory-die front metal interconnect structures and first memory-die front bonding structures;
providing a first memory controller die comprising a first controller-die substrate, a first memory controller circuit configured to control operation of the first memory die and located on the first controller-die substrate, and first controller-die front dielectric material layers embedding first controller-die front metal interconnect structures and first controller-die front bonding structures;
bonding the first controller-die front bonding structures to the first memory-die front bonding structures;
removing the first carrier substrate; and
forming a first inter-die connection via structure through the first memory-die dielectric material portion and a first subset of the first controller-die front dielectric material layers and directly on one of the first controller-die front metal interconnect structures.

19. The method of claim 18, wherein:
the first memory controller die comprises a first through-substrate via structure vertically extending through the first controller-die substrate; and
an electrically conductive path from the first inter-die connection via structure to the first through-substrate via structure is formed upon formation of the first inter-die connection via structure.

20. The method of claim 18, further comprising:
forming first memory-die backside dielectric material layers embedding first memory-die backside metal interconnect structures and first memory-die backside bonding structures on the first inter-die connection via structure;
physically exposing an end surface of the first through-substrate via structure by thinning the first controller-die substrate; and
forming first controller-die backside dielectric material layers embedding first controller-side backside metal interconnect structures and first controller-die backside bonding structures on the first through-substrate via structure.
